(19) United States
(12) Patent Application Publication
(10) Pub. No.: US 2020/0056092 A1
(43) Pub. Date: Feb. 20, 2020

(54) COMPOSITION AND METHOD COMPRISING OVERCOATED QUANTUM DOTS

(71) Applicant: Triad National Security, LLC, Los Alamos, NM (US)

(72) Inventors: Victor I. Klimov, Los Alamos, NM (US); Hongbo Li, Los Alamos, NM (US); Kaifeng Wu, Los Alamos, NM (US); Jaehoon Lim, Los Alamos, NM (US)

(73) Assignee: Triad National Security, LLC, Los Alamos, NM (US)

(21) Appl. No.: 16/551,408

(22) Filed: Aug. 26, 2019

Related U.S. Application Data
(63) Continuation of application No. 15/587,023, filed on May 4, 2017, now abandoned.
(60) Provisional application No. 62/331,847, filed on May 4, 2016.
(60) Provisional application No. 62/376,754, filed on Aug. 18, 2016.

(51) Int. Cl. C09K 11/02; C09K 11/88

(52) U.S. Cl. CPC C09K 11/025; C09K 11/883; Y10S 977/948; B82Y 40/00; Y10S 977/824; Y10S 977/783; Y10S 977/774; Y10S 977/892

(57) ABSTRACT

Disclosed herein are embodiments of a coated type-I quantum dot comprising a core and a shell, and a silica layer, and a method for making the quantum dot. The quantum dot may be a thick-shelled quantum dot. Also disclosed are embodiments of a composition comprising one or more coated quantum dots and a polymer. The composition may be a luminescent solar concentrator. Device comprising the composition are disclosed. The device may comprise the composition, such as a luminescent solar concentrator, applied to a substrate, such as glass. The device may be a window or a solar module. Also disclosed is a method of applying the composition to the substrate to form a thin film luminescent solar concentrator.

### CROSS REFERENCE TO RELATED APPLICATION

This application is a continuation of U.S. patent application Ser. No. 15/587,023, filed on May 4, 2017, which claims the benefit of the earlier filing date of U.S. provisional patent application No. 62/331,847, filed May 4, 2016, and U.S. provisional patent application No. 62/376,754, filed Aug. 18, 2016, all of which are incorporated herein by reference in their entirety.

### ACKNOWLEDGMENT OF GOVERNMENT SUPPORT

This invention was made with government support under Contract No. DE-AC52-06NA25396 awarded by the U.S. Department of Energy. The government has certain rights in the invention.

### FIELD

Disclosed embodiments concern a composition comprising an overcoated type-I quantum dot, a luminescent solar concentrator comprising the type-I quantum dots and a polymer, devices comprising the luminescent solar concentrator, and methods for use and manufacture.

### BACKGROUND

Luminescent solar concentrators (LSC) are light-management devices that can serve as large-area sunlight collectors for photovoltaic (PV) cells. An LSC typically comprises a slab of transparent material (e.g., glass or plastic) impregnated or coated with highly emissive fluorophores. Following absorption of solar light impinging onto a larger-area face of the slab, LSC fluorophores re-emit photons at a lower energy and these photons are guided by total internal reflection to the device edges where they are collected by photovoltaics. If the cost of an LSC is much lower than that of a photovoltaic cell of a comparable area, and the LSC's efficiency is sufficiently high, then by applying these devices in place of photovoltaic cells one can achieve a considerable reduction in the cost of solar electricity. Semi-transparent LSCs can also enable new types of devices such as solar or photovoltaic windows that could turn presently passive building facades into power generation units.

Colloidal quantum dots (QDs) have been actively explored in the context of LSC applications that capitalize on quantum dot properties such as widely tunable absorption and emission spectra, high photostability, and solution processibility. These structures can also be tailored in such a way as to greatly reduce losses to re-absorption (self-absorption) of guided light by using the concept of “Stokes-shift engineering” implemented via shape control, hetero-structuring, and/or impurity doping. Demonstrated approaches include the use of core/thick-shell “giant” quantum dots (g-QDs), Mn- and Cu-doped quantum dots, type-II hetero-structures, and ternary IIIIVI₂ quantum dots.

In most of the reported cases, LSC fluorophores have been embedded into a polymer matrix forming an LSC waveguide. A commonly applied polymer material has been poly(methyl methacrylate) or PMMA fabricated via in-situ polymerization. However, poor compatibility between PMMA and hydrophobic quantum dots detrimentally effects the LSC performance. One problem is quantum dot passivation degradation, which causes a drop in the photoluminescence (PL) quantum yield (QY). Another detrimental effect is quantum dot aggregation during the polymerization process, which leads to additional quenching of quantum dot emission due to inter-dot exciton transfer. Furthermore, the formation of quantum dot clusters leads to increased light scattering, causing a quantum dot/polymer slab to have a hazy appearance.

Hydrophobic monomers such as lauryl methacrylate (LMA), or special cross-linking agents, does not eliminate the quantum dot aggregation problem. Furthermore, it involves a more complicated and time-consuming quantum dot incorporation procedure, which increases the overall cost of devices. Independent of a choice of a specific material, the long-term stability of polymers and especially the robustness of their optical properties under solar irradiation are still unaddressed issues. Additionally, even in a freshly prepared polymer waveguide unavoidable fluctuations in the refractive index due to fluctuations in material's density can lead to considerable losses due to scattering.

### SUMMARY

Disclosed herein are embodiments of a coated type-I quantum dot and a composition comprising the quantum dot, that address these issues. The coated type-I quantum dot may comprise a type-I quantum dots comprising a core and a shell, and a silica coating. The shell may have a thickness of from 10 to 40 or more monolayers, such as from 10 to 30 monolayers, or from 10 to 20 monolayers. Alternatively, the shell may have a thickness of from 3 nm to 12 nm or more, such as from 3 nm to 10 nm. The core may be CdSe, CdTe, Si, CdSe₁₋ₓSₓ, Cd₁₋ₓZnₓSe, InAs, Cd₃P₂, CuFeS₂, InₓGa₁₋ₓP, CuInSe₂₋₂ₓS₂ₓ, AgInSe₂₋₂ₓS₂ₓ, (ZnS)ₓ(CuInS₂)₁₋ₓ, or (ZnSe)ₓ(CuInSe₂)₁₋ₓ, and/or the shell may be Cd₁₋ₓZnₓS, Cd₁₋ₓZnₓSe, ZnSe_{1-y}S_{y}, Cd₁₋ₓZnₓSe_{1-y}S_{y}, CdSe, InP, CuInSe₂₋₂ₓS₂ₓ, AgInSe₂₋₂ₓS₂ₓ, or GaP_{1-y}N_{y}, where x is from 0 to 1 and y is from 0 to 1. In some embodiments, x is from greater than 0 to less than 1, and/or y is from greater than 0 to less than 1. The quantum dot may have a core/shell structure selected from CdSe/Cd₁₋ₓZnₓS, CdSe/Cd₁₋ₓZnₓSe, CdSe/ZnSe_{1-y}S_{y}, CdSe/Cd₁₋ₓZnxSe_{1-y}S_{y}, CdTe/ZnSe_{1-y}S_{y}, CdTe/Cd₁₋ₓZnxSe_{1-y}S_{y}, CdSe₁₋ₓSx/Cd_{1-y}Zn_{y}S, Cd₁₋ₓZnₓSe/ZnSe_{1-y}S_{y}, InAs/CdSe, InAs/InP, InAs/Cd₁₋ₓZnxSe_{1-y}S_{y}, Cd₃P₂/ZnSe_{1-y}S_{y}, InxGa₁₋ₓP/ZnSe_{1-y}S_{y}, InₓGa₁₋ₓP/GaP_{1-y}N_{y}, CuInSe₂₋₂ₓS₂ₓ/ZnSe_{1-y}S_{y}, AgInSe₂₋₂ₓS₂ₓ/ZnSe_{1-y}S_{y}, or (ZnSe)ₓ(CuInSe₂)₁₋ₓ/ZnSe_{1-y}S_{y} where x and y are as previously defined. In certain embodiments, the core of the type-I quantum dot is CdSe, and/or the shell is Cd₁₋ₓZnₓS, where x is from greater than 0 to less than 1, such as 0.1, 0.2, 0.3, 0.4, 0.5, 0.6, 0.7, 0.8, or 0.9. In some embodiments, x is 0.5. The silica coating may have a coating thickness of from 1 nm or less to 30 nm or more, such as from 3 nm to 15 nm, or about 4 nm for certain disclosed embodiments. In certain embodiments, the coated quantum dot comprises a CdSe core, a Cd_{0.5}Zn_{0.5}S shell having a shell thickness of from 3 nm to 10 nm, and a silica coating having a coating thickness of about 4 nm. Also disclosed is a composition comprising a type-I quantum dot and a silica coating.

Also disclosed are embodiments of a composition comprising a polymer and one or more disclosed coated type-I quantum dots. The composition may be a luminescent solar concentrator, and in some embodiments, the composition is a thin film luminescent solar concentrator that reduces the amount of polymer present, thereby reducing the polymer-associated issues. In some embodiments, the polymer is a poly acrylate, poly acryl methacrylate, polyolefin, polyvinyl, epoxy resin (polyepoxide), polycarbonate, polyacetate, polyamide, polyurethane, polyketone, polyester, polycyanoacrylate, silicone, polyglycol, polyimide, fluorinated polymer, polycellulose, poly oxazine, or a combination thereof, and in certain embodiments, the polymer is polyvinylpyrrolidone.

In some embodiments, the composition, such as a luminescent solar concentrator, comprises an amount of quantum dots, excluding a weight of the silica coating, of from 10 mgs to 250 mgs per gram of polymer, such as from 30 mgs to 150 mgs, or from 50 mgs to 75 mgs per gram of polymer, and in certain embodiments, the amount is from 60 mgs to 70 mgs per gram of polymer. In some embodiments, the one or more quantum dots are CdSe/Cd₁₋ₓZnₓS quantum dots, where x is from greater than zero to less than 1, such as 0.5, and the polymer is polyvinylpyrrolidone. The silica coating may have a coating thickness of from 3 nm to 10 nm.

Also disclosed herein are embodiments of a device comprising a substrate and a disclosed composition, such as a disclosed luminescent solar concentrator. The disclosed composition may be a thin film, such as a thin film luminescent solar concentrator, and may have a film thickness of from greater than zero to 1 mm, such as from 10 μm to 500 μm, or from 20 μm to 300 μm. The substrate may be glass, fiberglass, acrylic sheet, or a combination thereof, and in some embodiments, the substrate is glass. The device also may comprise one or more photovoltaic cells.

The device may be a window, and in some embodiments, the window comprises at least one window pane at least partially coated with a film comprising the disclosed composition. The window may comprise at least two window panes, and the composition is a thin film luminescent solar concentrator that at least partially covers an interior surface between the two window panes. In other embodiments, the device is a solar module, a solar panel, a solar lamp, a solar battery charging device, or a solar powered transport device. The device may further comprise one or more photovoltaic cells.

A building or transportation device having at least one window disclosed herein is also disclosed. The transportation device may be, for example, a ship, airplane, train, automobile, or space vehicle.

Also disclosed are embodiments of a method for making the silica coated type-I quantum dots, comprising forming a composition comprising type-I quantum dots, a surfactant, and a solvent; adding a silica precursor and an initiator to the composition; and isolating the coated type-I quantum dots. And embodiments of a method for making a device disclosed herein are also disclosed. The method may comprise forming a composition comprising one or more of the coated quantum dots disclosed herein, a polymer, and a solvent; applying the composition to a substrate; and evaporating the solvent. In some embodiments, applying the composition comprises using a doctor-blade technique.

The foregoing and other objects, features, and advantages of the invention will become more apparent from the following detailed description, which proceeds with reference to the accompanying figures.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic diagram of an approximate energy band structure of an exemplary CdSe/Cd₁₋ₓZnₓS giant quantum dots with x=0.5, as determined from inductively coupled plasma-optical emission spectroscopy, illustrating that the band offsets in the valence- and conduction bands are almost the same, at 0.3 eV.

FIG. 2 is a transmission electron microscopy (TEM) image of CdSe cores with a 4 nm mean diameter.

FIG. 3 is a TEM image of core/shell CdSe/Cd₁₋ₓZnₓS giant quantum dots synthesized according to the disclosed embodiments, illustrating the irregular shapes typical of thick-shell structures, with an inset, a high-resolution TEM image indicating a lack of apparent crystal defects.

FIG. 4 is a graph of count versus size, illustrating the quantum dot sizes for sample of thick-shell CdSe/Cd₁₋ₓZnₓS giant quantum dots from FIG. 3 with x=0.5 and the CdSe mean core diameter of 4 nm.

FIG. 5 is a graph of absorption versus wavelength, illustrating the absorption (black) and photoluminescence (gray) spectra of CdSe/Cd₁₋ₓZnₓS giant quantum dots indicating a large effective Stokes shift of 440 meV.

FIG. 6 is a photograph comparing a blank 2.54×2.54 cm² glass substrate (left), with the same substrate spin-coated with giant quantum dots with (middle) and without (right) silica shells.

FIG. 7 is a photograph of a spin-coated substrate containing giant quantum dots with silica shells, illustrating a wave-guiding effect under ultraviolet (UV) illumination.

FIG. 8 is a schematic diagram illustrating thin-film deposition using a doctor-blade method.

FIG. 9 is a photograph of an exemplary setup used to evaluate the performance of fabricated thin-film LSCs, and square-shaped LSCs fabricated on substrates with different size with edges masked by a carbon tape.

FIG. 10 is a photograph of a large-area LSC fabricated by the doctor-blade method with dimensions 91.4×30.5 cm² (36×12 in²).

FIG. 11 is a photograph of the LSC from FIG. 10 in sunlight, illustrating the high emissivity and strong waveguiding effect as indicated by brightly lit device edges.

FIG. 12 is a photograph of the LSC from FIG. 10 in weak UV light, illustrating the high emissivity and strong waveguiding effect as indicated by brightly lit device edges.

FIG. 13 is a schematic diagram of one embodiment of a device comprising a disclosed LSC.

FIG. 14 is a normalized graph of reaction times, illustrating the photoluminescence intensities of giant quantum dots as a function of reaction time during quantum dot overcoating with silica to produce silica shells with the average thickness of 5 nm after 40 hours.

FIG. 15 is a photograph of TEM images of individual CdSe/Cd₁₋ₓZnₓS giant quantum dots overcoated with silica shells, illustrating the different thicknesses of 5 nm, 9 nm, 14 nm and 19 nm.

FIG. 16 is a photograph of a large-area view of silica-coated giant quantum dots with the mean silica-shell thickness of 5 nm and overall particle sizes of 22.5±2.3 nm, illustrating that in all composite particles, the giant quantum dot were centrally located and instances of multiple giant quantum dots within the same shell were extremely rare.

FIG. 17 is a graph of count versus size, illustrating the particle sizes for the sample shown in FIG. 3 after overcoating the giant quantum dots with silica shells, to give an average composite particle size of 22.5 ±2.3 nm, and an average silica shell thickness of 5 nm.

FIG. 18 is a graph of photoluminescence quantum yield versus thickness of silica shell, illustrating that the emission efficiency of silica-coated giant quantum dots in ethanol is independent of shell thickness and varies within 5% of the average value of 70%, which is the value of uncoated giant quantum dots.

FIG. 19 is a normalized graph of wavelengths, illustrating the photoluminescence spectra of uncoated (bottom) and silica-coated (top; 5 nm shell thickness) giant quantum dots dissolved in toluene and methanol respectively, showing that the spectra are nearly identical, indicating no spectral distortion due to silica coating.

FIG. 20 is a graph of photoluminescence intensity versus time, illustrating the photoluminescence dynamics of uncoated and silica-coated giant quantum dots dissolved in toluene and methanol, respectively.

FIG. 21 is a graph of photoluminescence intensity versus time, illustrating that the photoluminescence decay in silica-coated giant quantum dots is almost independent of shell thickness, with an average lie time constant of 26 ns (±1 ns).

FIG. 22 is a normalized graph of photoluminescence in arbitrary units versus wavelength, comparing the photoluminescence spectra of solutions (dashed lines) and films (solid lines), of uncoated giant quantum dots (bottom) and silica-coated giant quantum dots (top), with the solutions dissolved in toluene and methanol, respectively.

FIG. 23 is a graph of photoluminescence quantum yield versus composition, showing the photoluminescence quantum yields of solution and film samples of coated and uncoated giant quantum dots, illustrating the difference in photoluminescence quenching due to energy transfer (ET) between uncoated and silica-coated giant quantum dots in film and solution samples.

FIG. 24 is a graph of relative photoluminescence intensity versus exposure time in air, illustrating the respective drop in photoluminescence intensity of spin-coated films of silica-coated and uncoated giant quantum dots exposed to air and room light in a four month trial.

FIG. 25 is a graph of relative photoluminescence intensity versus temperature, illustrating the thermal stability of silica-coated giant quantum dots compared to uncoated giant quantum dots.

FIG. 26 is a graph of absorption versus wavelength, illustrating an absorption spectrum of an exemplary fabricated thin-film LSC.

FIG. 27 is a graph of photoluminescence intensity versus optical path, illustrating the spectrally integrated intensity of photoluminescence from the LSC edge as a function of separation of the excitation spot and the edge, with an inset schematic diagram illustrating the optical path.

FIG. 28 is a schematic diagram of a fiber-in-fiber-out, integrating-sphere setup used to quantify various efficiencies of exemplary fabricated LSCs.

FIG. 29 is a graph of photoluminescence intensity versus wavelength, illustrating the spectra of total LSC emission measured for the unmasked device (black), the face emission obtained for the device with masked edges (light gray) and the edge-emission spectrum (dark gray) obtained by subtracting the other two spectra.

FIG. 30 is a graph of efficiency versus LSC length and area, illustrating the LSC photoluminescence quantum yield and edge emission efficiency of exemplary fabricated devices as a function of their size.

FIG. 31 is a graph of intensity versus wavelength, illustrating the photoluminescence spectra of total, edge, and face emission in a 1 inch LSC, with an insert showing the spectra in a normalized form.

FIG. 32 is a graph of intensity versus wavelength, illustrating the photoluminescence spectra of total, edge, and face emission in a 2 inch LSC, with an insert showing the spectra in a normalized form.

FIG. 33 is a graph of intensity versus wavelength, illustrating the photoluminescence spectra of total, edge, and face emission in a 3 inch LSC, with an insert showing the spectra in a normalized form.

FIG. 34 is a graph of intensity versus wavelength, illustrating the photoluminescence spectra of total, edge, and face emission in a 4 inch LSC, with an insert showing the spectra in a normalized form.

FIG. 35 is a graph of external optical efficiency and concentration factor versus LSC length and area, illustrating the similarity between the measured (triangles) and calculated ηₑₓ values (solid line), the measured (open circles) and calculated (dashed line) values for the concentration factor C, for photoluminescence quantum yield of 70%, and also providing calculated values for ηₑₓ (solid) and C (dashed) for photoluminescence quantum yields of 90% and 100%. The values of ηₑₓ (solid blue triangles) and C (solid blue circles) for 10.16 and 20.32 cm LSCs derived from electro-optical measurements are also included.

### DETAILED DESCRIPTION

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims. Unless otherwise indicated, all numbers expressing quantities of components, molecular weights, percentages, temperatures, times, and so forth, as used in the specification or claims are to be understood as being modified by the term “about.” Accordingly, unless otherwise indicated, implicitly or explicitly, the numerical parameters set forth are approximations that may depend on the desired properties sought and/or limits of detection under standard test conditions/methods. When directly and explicitly distinguishing embodiments from discussed prior art, the embodiment numbers are not approximates unless the word “about” is recited.

### I. QUANTUM DOTS

A. Type-I Giant Quantum Dots with a High Photoluminescence Quantum Yield and a Tunable Effective Stokes Shift

In some embodiments, type-I quantum dots are used as LSC fluorophores. In type-I quantum dots both the conduction and valence band edges of the core are within the bandgap of the shell. This results in both the electrons and the holes being confined to the core. Previously CdSe/CdS quantum dots have been used as LSC fluorophores. However, with a pure-phase CdS shell, the conduction-band-offset at the core/shell interface is insufficient to confine an electron to the core. This corresponds to a so-called quasi-type-II localization regime where the hole is core-confined, while the electron is delocalized across the entire quantum dot volume. In this situation the electron wave function can sample defects at the shell surface, which may reduce the photoluminescence quantum yield. Further, a nearly bulk-like character of the electron wave function limits the range of spectral tunability of both the photoluminescence and the onset of strong absorption, which is dominated by the shell and thus fixed by the CdS band gap.

Disclosed herein are embodiments of a composition comprising thick-shell giant quantum dots that are useful as LSC fluorophores. In addition to improving the overall stability of the quantum dots, a thick shell may help isolate the core from the outer environment and at least partially eliminate nonradiative decay pathways related to surface defects. Furthermore, a thick-shell on the quantum dot may help reduce the Auger recombination rate and thus increase the emission efficiency of charged excitons that might form as a result of uncontrolled photoionization. Additionally, a thick shell may help suppress inter-dot exciton transfer. This helps maintain a high photoluminescence quantum efficiency even in the case of quantum dot aggregation, which is a frequent problem in quantum dot/polymer composites.

As used herein, the terms “thick-shell,” “giant” or “g-” refer to a quantum dot having a shell of 8 or more monolayers, such as from 10 to 40 or more monolayers, from 10 to 30 monolayers, from 10 to 25 monolayers or from 10 to 20 monolayers. The terms also may be combined, such as in thick-shell giant quantum dot. Typically, a monolayer is about 3 to 4 angstroms. Thus a thick-shell or giant quantum dot may have a shell thickness of 2 nm or more, such as from 3 nm to 12 nm, from 3 nm to 10 nm, or from 4 nm to 8 nm.

In some embodiments, the giant quantum dots are type-I quantum dots having a core/shell structure. Exemplary core compositions include, but are not limited to, CdSe, CdTe, Si, CdSe₁₋ₓSx, Cd₁₋ₓZnₓSe, InAs, Cd₃P₂, CuFeS₂, InₓGa₁₋ₓP, CuInSe₂₍₁₋ₓ₎S₂ₓ, AgInSe₂₍₁₋ₓ₎S₂ₓ, and (ZnS)ₓ(CuInS₂)₁₋ₓ or (ZnSe)ₓ(CuInSe₂)₁₋ₓ alloys, where x is from 0 to 1, and may be from greater than zero to less than 1. The shell may be Cd₁₋ₓZnₓS, Cd₁₋ₓZnₓSe, ZnSe_{1-y}S_{y}, Cd₁₋ₓZnₓSe_{1-y}S_{y}, CdSe, InP, CuInSe₂₍₁₋ₓ₎S₂ₓ, AgInSe₂₍₁₋ₓ₎S₂ₓ, or GaP_{1-y}N_{y}, where x and y independently are from 0 to 1, and may be from greater than zero to less than 1. In some embodiments of the core and/or shell, each of x and y independently are 0.1, 0.2, 0.3, 0.4, 0.5, 0.6, 0.7, 0.8, or 0.9. Exemplary type-I quantum dots include, but are not limited to, CdSe/Cd₁₋ₓZnₓS, CdSe/Cd₁₋ₓZnₓSe, CdSe/ZnSe_{1-y}S_{y}, CdSe/Cd₁₋ₓZnₓSe_{1-y}S_{y}, CdTe/ZnSe_{1-y}S_{y}, CdTe/Cd₁₋ₓZnₓSe_{1-y}S_{y}, CdSe₁₋ₓSx/Cd_{1-y}Zn_{y}S, Cd₁₋ₓZnₓSe/ZnSe_{1-y}S_{y}, InAs/CdSe, InAs/InP, InAs/Cd₁₋ₓZnₓSe_{1-y}S_{y}, Cd₃P₂/ZnSe_{1-y}S_{y}, InₓGa₁₋ₓP/ZnSe_{1-y}S_{y}, InₓGa₁₋ₓP/GaP_{1-y}N_{y}, CuInSe₂₍₁₋ₓ₎S₂ₓ/ZnSe_{1-y}S_{y}, AgInSe₂₍₁₋ₓ)S₂ₓ/ZnSe_{1-y}S_{y}, and (ZnSe)ₓ(CuInSe₂)₁₋ₓ/ZnSe_{1-y}S_{y} where x and y are as previously defined.

Certain disclosed embodiments concern giant quantum dots comprising a CdSe core and a Cdi,ZnₓS shell, where x is from 0 to 1, or from greater than 0 to less than 1. In some embodiments, x is 0.1, 0.2, 0.3, 0.4, 0.5, 0.6, 0.7, 0.8, or 0.9, and in particular embodiments, x is 0.5.

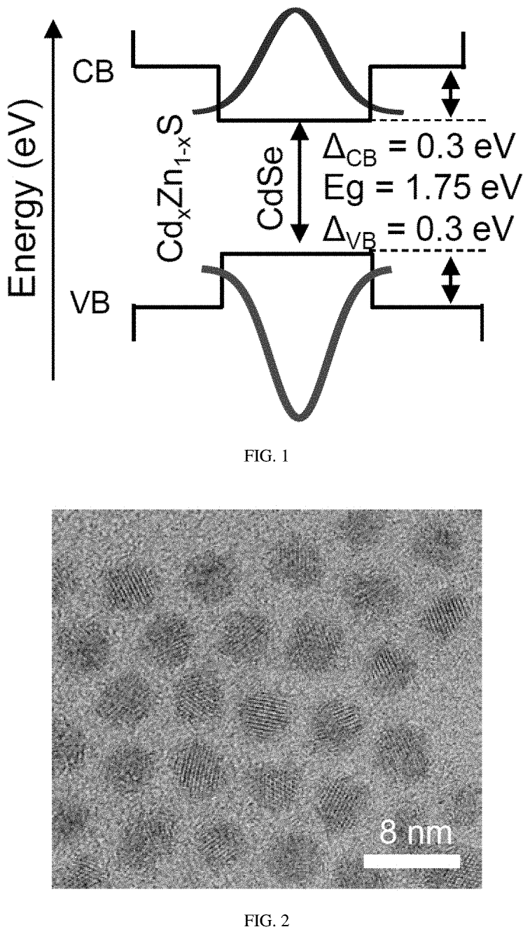

In some embodiments, the fraction of Zn in the shell, such as a Cd₁₋ₓZnₓS shell, is selected to result in a conduction band offset that is sufficiently large to substantially confine the electron to the CdSe core. This corresponds to the restoration of type-I localization characteristic of CdSe core-only structures, but with the benefit of a thick energetic barrier isolating both the electron and the hole wave functions from surface defects and deleterious effects of environment (FIG. 1). FIG. 1 shows that the alloyed composition of the Cd₁₋ₓZnₓS shell increases a conduction-band offset compared to conventional CdSe/CdS giant quantum dots, which allows for confining an electron in the core region. In addition to the improved photoluminescence quantum yield and stability compared to more traditional CdSe/CdSe giant quantum dots, the use of thick-shell, type-I hetero-structures extends the range of spectral tunability of both photoluminescence and the absorption onset by combining the core-size control (for changing photoluminescence wavelength) with the control of the shell composition (for changing the position of absorption onset).

In addition, the disclosed giant quantum dots exhibit a large, tunable effective Stokes shift (Δ_{S}>400 meV), which is approximately equal to the energy separating the emitting state of the CdSe core and the band gap of the quasi-bulk Cd₁₋ₓZnₓS shell. This minimizes the losses due to re-absorption of guided light, which occurred in previously reported CdSe/CdS giant quantum dots. Additionally, an added benefit of the thick-shell CdSe/Cd₁₋ₓZnₓS giant quantum dots is the facile tunability of both the emission wavelength and As.

B. Synthesis

In certain disclosed embodiments, CdSe/Cd₁₋ₓZnₓS giant quantum dots, such as quantum dots where x is 0.5, are synthesized by a successive shell growth procedure. Briefly, cadmium, zinc and sulfur precursors are repeatedly added to CdSe cores at a suitable temperature, such as from 200° C. to 400° C. or more, from 250° C. to 350° C., or about 300° C., until the shell thickness reaches a desirable range, such as from 2 nm to 12 nm or more, from 3 nm to 12 nm, from 3 nm to 10 nm, from 3 nm to 8 nm or from 3 nm to 6 nm. This high-temperature synthetic scheme minimizes the reaction time (to less than 3 hours in some embodiments), and also produces high quality giant quantum dots with minimal amounts of crystalline defects, such as misfit dislocations and/or atomic vacancies. Additional information concerning how to make the type-I quantum dots is included in the Examples. Transmission electron microscopy (TEM) studies indicate a high monodispersity of CdSe cores. The cores may have a mean radius of from 1 nm to 4 nm or more, such as from 2 nm to 3 nm, and in certain embodiments, the cores had a mean radius of about 2 nm. The cores also may have a size dispersion of from 0% to 25%, such as from 0% to 20%, from 0% to 15%, from 0% to 10%, or from 0% to 5%, and in certain disclosed embodiments, the core size dispersion was less than 10% (FIG. 2).

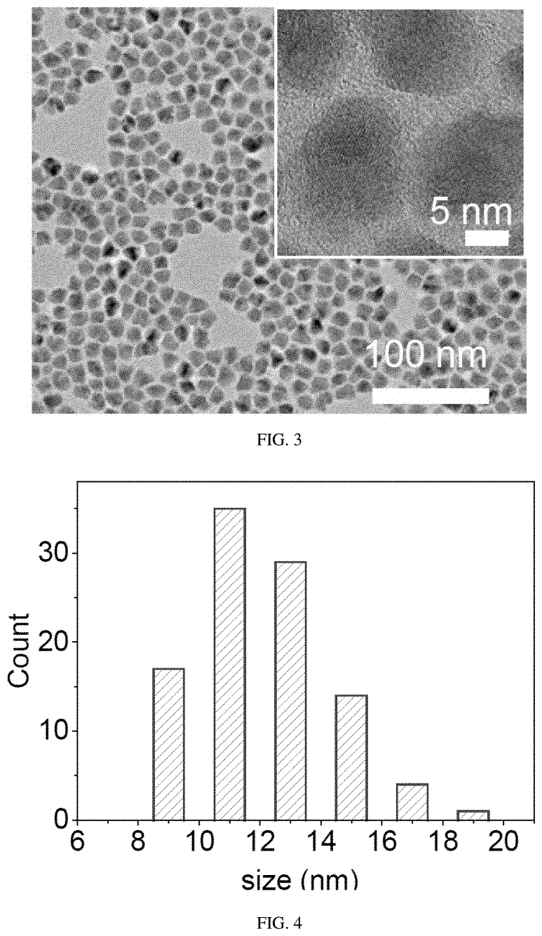

In some embodiments, the average diameter of the quantum dots at the end of shell growth reaction is from less than 4 nm to 25 nm or more, such as from 4 nm to 25 nm, from 7 nm to 20 nm, from 10 nm to 15 nm, or about 12 nm. The size dispersion of the quantum dots may be from 0% to 25%, such as from 0% to 20%, from 0% to 15%, or from 0% to 10%. In certain embodiments, CdSe/Cd_{0.5}Zn_{0.5}S giant quantum dots had an average diameter of from 11.5 nm to 12.5 nm, such as from 12.0 nm to 12.2 nm (about 15% size dispersion; FIGS. 3 and 4), indicating that the average shell thickness was about 4 nm. The final particles may have irregular shapes that are typical of thick-shell structures (FIG. 3).

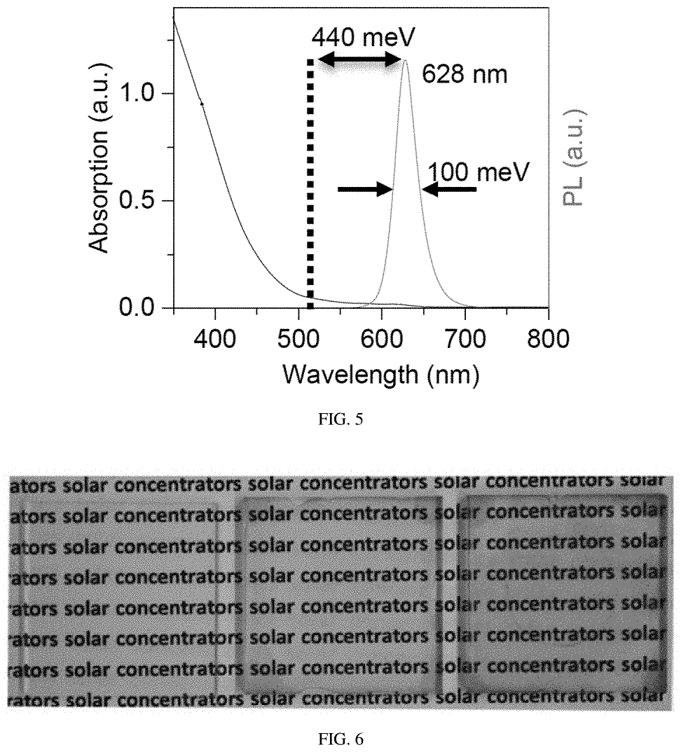

According to high-resolution TEM images (inset of FIG. 3), the synthesized hetero-quantum dots typically are single crystals without apparent defects such as misfit dislocations. This suggests that a thick Cd₁₋ₓZnₓS alloyed shell grows epitaxially on CdSe core, which is in contrast to extensively-studied CdSe/CdS giant quantum dots that often display crystalline defects even at small shell thicknesses. Without being bound to a particular theory, the improved crystallinity may result in the photoluminescence quantum yield of the type-I giant quantum dots being increased compared to that of the CdSe/CdS giant quantum dots of comparable sizes. A typical emission efficiency of certain embodiments is about 70%, compared to about 40% for a similarly sized CdSe/CdS giant quantum dots. The photoluminescence peak of the CdSe/Cd₁₋ₓZnₓS giant quantum dots is at about 628 nm and the onset of strong absorption associated with the thick alloyed shell is approximately at 460 nm (FIG. 5). These values correspond to the effective Stokes shift of about 440 meV, which is sufficiently large to considerably reduce self-reabsorption of emitted light, an advantageous feature for an LSC fluorophore.

C. Overcoating Type-I Quantum Dots with Silica Shells

In some embodiments, the type-I quantum dots, such as CdSe/Cd₁₋ₓZnₓS giant quantum dots, are hydrophobic and not compatible with the polar solvents typically used when encapsulating quantum dots in a polymer matrix. Several approaches have been developed for transferring hydrophobic quantum dots into polar media including the exchange of original ligands for bi-functional molecules, or using additional capping with amphiphilic polymers or dendron molecules. These methods, however, are often not effective in stabilizing large-size quantum dots, such as the disclosed giant quantum dots, in polar solvents due to their fairly small surface-to-volume ratio. Furthermore, these surface treatment procedures are frequently accompanied by a drop in the photoluminescence quantum yield due to the introduction of trap states acting as hole or electron scavengers.

Instead of modifying the composition of the molecular ligand layer, certain disclosed embodiments comprise type-I quantum dots coated with an inorganic silica shell. The silica shell provides improved solubility for the quantum dots in polar solvents, and may also enhance the stability of the quantum dots. In some embodiments, the quantum dots are giant quantum dots. Previous attempts to overcoat non-type-I quantum dots with silica involved an oil-in-water micro-emulsion reaction or very slow silanization of the quantum dots to replace surface ligands with partially hydrolyzed tetraethyl orthosilicate (TEOS). However, at best these approaches only resulted in retaining about 40% of the original photoluminescence quantum yield before the silica coating was applied.

In some embodiments, the disclosed quantum dots are coated by a micro-emulsion reaction, which allows for a highly accurate control of the shell thickness.

Additionally, the reaction substantially avoids the formation of quantum dot clusters during the encapsulation procedure, which is a well-known problem of other methods used to grow silica shells. The quantum dots are dispersed in a suitable solvent, typically a non-polar, aprotic solvent such as toluene, xylene, cyclohexane or a combination thereof. The dispersion is added to a solution of a surfactant in a suitable solvent. The surfactant can be any surfactant suitable to facilitate the silica overcoating of the quantum dots. In some embodiments, the surfactant is a polyoxyethylene nonylphenylether, such as IGEPAL®CO-520. The solvent can be any solvent suitable to facilitate the reaction, and may be an aprotic and/or non-polar solvent, such as cyclohexane, hexane, pentane, heptane, toluene, xylene or combinations thereof. A silica precursor is added to the mixture. The silica precursor can be any silica precursor suitable for producing an overcoat of silica on the quantum dots. In some embodiments, the silica precursor is a tetraalkyl orthosilicate, such as tetraethyl orthosilicate (TEOS) or tetramethyl orthosilicate. The reaction may be initiated by a suitable initiator. The initiator may be an ammonium initiator, particularly ammonium salts such as ammonium hydroxide or alkylammonium hydroxides such as tetramethylammonium hydroxide and tetraethylammonium hydroxide. The reaction proceeds at a temperature and for an amount of time suitable to produce a desired silica thickness. In some embodiments, the amount of time is from 5 hour or less to 100 hours or more, such as from 10 hours to 90 hours, from 15 hours to 80 hours, from 20 hours to 70 hours, from 30 hours to 60 hours, or from 35 hours to 50 hours. In certain embodiments, the amount of time is about 40 hours. In some embodiments, the temperature is from 15° C. or less to 40° C. or more, such as from 15° C. to 35° C., from 18° C. to 30° C. or from 20° C. to 25° C. In certain embodiments, the reaction proceeds at room or ambient temperature, such as without external heating or cooling. The thickness of the silica shells can also be controlled by varying the amounts of the silica precursor, and the concentration and/or amount of quantum dots. The shell thickness may vary from 1 nm to 30 nm or more, such as from 2 nm to 25 nm, from 3 nm to 20 nm, from 3 nm to 15 nm, from 3 nm to 10 nm, or from 3 nm to 6 nm.

Surprisingly, giant quantum dots, such as type-I giant quantum dots, and particularly CdSe/Cd₁₋ₓZnₓS giant quantum dots, overcoated with silica by the disclosed method retain greater than 90% of the original photoluminescence quantum yield, such as greater than 95%, greater than 98% or greater than 99% of the original photoluminescence quantum yield. Without being bound to a particular theory, this improvement in retention of photoluminescence quantum yield compared to the previously disclosed 40% retention, may be due to the mild temperature and/or long reaction times used in the method resulting in fewer defects.

### II. FABRICATION OF THIN-FILMS

A common method for fabricating quantum-dot/polymer composites such as those used in LSC waveguides has been bulk polymerization of precursors containing monomers and quantum dots. However, due to the use of thermal radical initiators (such as azo-compounds and peroxides), this procedure often quenches quantum dot emission through effects such as quantum dot aggregation, degradation of surface passivation, and oxidation of the quantum dots. Although thick-shell giant quantum dots suffer from these effects to a lesser degree compared to core-only or thin-shell structures, a partial loss of photoluminescence quantum yield is still a common problem with thick-shell giant quantum dots. Furthermore, all-polymer LSCs fabricated via bulk polymerization suffer from considerable optical losses due to scattering at imperfections within the polymer matrix.

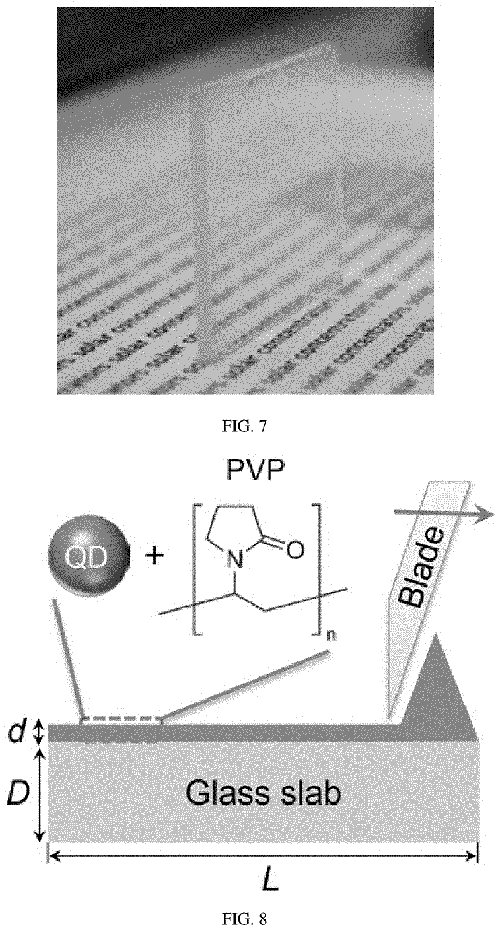

One approach to at least partially mitigate the problems associated with all-polymer LSC waveguides, such as the effects of scattering, is to minimize the amount of the polymer in the LSC waveguide. It is possible to accomplish this goal via direct deposition of a layer of quantum dots or quantum dot/polymer composites onto high-optical-quality glass slabs using, for example, spin coating. The loss to optical scattering in such structure due to imperfections in the polymer matrix is typically reduced in direct proportion to the ratio between the overall waveguide thickness and the thickness of the polymer layer. As illustrated in FIGS. 6 and 7, a strong wave-guiding effect (emission from glass edges) was observed in films comprising the disclosed silica-encapsulated quantum dots prepared by spin coating on glass slides. Other techniques for applying the film on to a substrate include, but are not limited to, electrospinning, layer-by-layer deposition, dip-coating, inkjet printing, painting, screen printing, gravure printing, curtain coating, slot die coating, spraying or a doctor-blade method, or any combination thereof. The quantum dot film may be applied to one or more surfaces of the substrate, such as on two sides of a slab of glass.

However, while being appropriate for fabrication of proof-of-principle devices, techniques such as spin coating, dip-coating, printing or spraying are typically unsuitable for large-scale production of LSCs due to a large amount of material wasted during the deposition process and/or difficulties in producing large-area films of a uniform thickness. For example, spin-coating can result in as much as 90% of the polymer mixture being wasted, making the technique expensive for commercial production.

Disclosed herein are embodiments of a method of making a thin-film composition, such as a thin-film LSC, comprising thin-film fabrication by a doctor-blade technique. This method can be applied to flat substrates of virtually any dimensions, including large area substrates, and compositions, and produces highly uniform films with a precisely controlled thickness. The substrates may be transparent substrates. Additionally, the technique is very reproducible, comparatively inexpensive, and there is only minimal, if any, wastage, making the technique attractive for commercial operations. Suitable substrates include, but are not limited to, glass, including window glass; fiberglass; acrylic sheet, such as Perspex®, Plesiglas®, and poly(meth methacrylate), PVA, polyethylene terephthalate/PET, polyethylene naphthalate (PEN), polycarbonate (PC), polyethersulfone (PES), and polyimide (PI). In certain embodiments, the substrate is glass.

Disclosed herein are embodiments of high quality thin film LSCs that are prepared both manually using a glass rod and mechanically using a doctor-blade apparatus. In the film fabrication process, a viscous slurry is made by dispersing and/or dissolving silica-coated quantum dots and a polymer in a suitable solvent. The polymer may be any polymer suitable for forming the LSC. In some examples, the polymer comprises poly acrylate, poly acryl methacrylate, polyolefin, polyvinyl, epoxy resin (polyepoxide), polycarbonate, polyacetate, polyamide, polyurethane, polyketone, polyester, polycyanoacrylate, silicone, polyglycol, polyimide, fluorinated polymer, polycellulose, poly oxazine, or a combination thereof. Exemplary polymers include, but are not limited to, polyethylene, polypropylene, polymethylpentene, polybutene-1, polyisobutylene, ethylene propylene rubber, ethylene propylene diene monomer rubber, polyvinyl chloride, polyvinylpyrrolidone (PVP), polybutadiene, polystyrene, polyvinyl acetate, polyvinyl alcohol, polyacrylonitrile, bisphenol-A, bisphenol-F, polytetrafluoroethylene, polyvinylfluoride, polyvinylidene fluoride, polychlorotrifluoroethylene, ethylene-carbon monoxide co-polymer, polyglycolide, polylactic acid, polycaprolactone, polyhydroxyalkanoate, polyhydroxybutyrate, polyethylene adipate, polybutylene succinate, polyethylene glycol, methyl cellulose, hydroxyl methyl cellulose, polymethyl methacrylate, polymethyl acrylate, polyethyl acrylate, polylauryl methacrylate, or combinations thereof. In some embodiments, a pre-polymerized solution is used for thin film fabrication. The pre-polymerized solution comprises one or more monomers and at least one pre-polymerized polymer. After film deposition, polymerization is completed. Polymerization may be completed using an initiator, such as a UV-initiator, for example, UV-initiator Darocures 4265, to polymerize the rest of monomer. In the case of, for example, polylauryl methacrylate (PLMA) a suitable cross-linking agent is ethylene glycol dimethacrylate/EGDM. In certain embodiments, the polymer is polyvinylpyrrolidone (PVP) which, without being bound to a particular theory, can use the carbonyl group and nitrogen atom in the pyrrolidone ring to coordinate to the quantum dot. This may help disperse the quantum dots homogeneously within the polymer matrix and help avoid formation of aggregates.

The solvent can be any solvent that facilitates the production of an LSC. In some embodiments, the solvent is a solvent that dissolves the polymer. The solvent may be a polar and/or protic solvent, and in some embodiments, the solvent is an alcohol, such as a Ci-Cio alcohol, particularly methanol, ethanol, propanol, isopropanol or a combination thereof. In certain disclosed embodiments, the solvent is ethanol. In other embodiments, the solvent is a non-polar solvent, such as toluene or cyclohexane. In some embodiments, the weight of quantum dots used and/or present in a film, not including the weight of the silica overcoating, per gram of polymer is from greater than zero to 300 mgs or more, such as from 2 mgs to 300 mgs, from 10 mgs to 250 mgs, from 20 mgs to 200 mgs, from 30 mgs, to 150 mgs, from 40 mgs to 100 mgs, from 50 mgs to 75 mgs, or from 60 mgs to 70 mgs per 1 gram of polymer. In some embodiments, for a 1 inch square substrate with a 50 μm thick film, the amount of quantum dots used is from 2 mgs to 5 mgs, typically about 2.5 mgs. In embodiments comprising a 1 meter square substrate and 50 μm thick film, from 2 to 6 grams, such as about 4 grams of quantum dots are typically used. In certain disclosed embodiments, 66.6 mgs of quantum dots, not including the weight of the overcoated silica, were used per gram of polymer, such as 40 mgs quantum dots to 0.6 g polymer.

The viscous slurry is placed on a glass substrate in front of a blade (FIG. 8). The blade is translated over the substrate at a suitable speed, which optionally may be a constant speed, leaving behind a viscous quantum dot/polymer layer, where the quantum dots are dispersed in the polymer. Suitable blade speeds include any blade speed that produces a desired quantum dot/polymer layer on the substrate. Suitable speeds may be from greater than zero mm per second, to 500 mm/s or more, such as from 50 mm/s to 400 mm/s, from 100 mm/s to 300 mm/s, from 150 mm/s to 250 mm/s, or about 200 mm/s. The layer becomes a highly uniform, transparent film upon evaporation of the solvent. Adjusting the size of the gap between the blade and the substrate allows the film thickness to be controlled. The final thickness of the dried film may also depend on the viscosity of the slurry and the blade-translation speed. The viscosity may be from 2 to 100 pascal seconds. The film thickness may be from greater than zero to 1 mm, such as from 5μm to 750 μm, from 10 μm to 500 μm, from 20 μm to 300 μm, from 30 μm to 150 μm or from 40 μm to 100 μm. In certain disclosed embodiments, the gap was fixed at 100 μm, and the resulting film thickness after solvent evaporation (d) was about 50 μm.

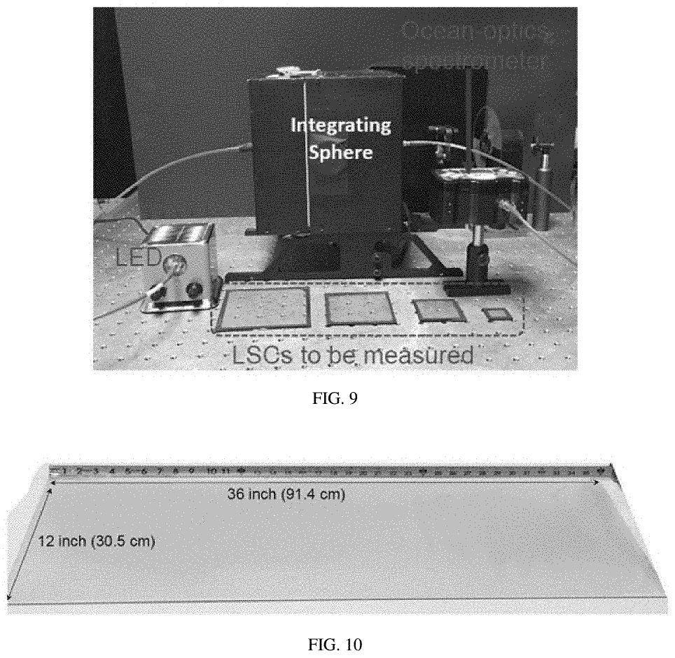

In some embodiments, square-shaped glass slabs with a thickness (D) of 1.59 mm and a side length (L) from 2.54 to 10.2 cm (1 to 4 inches) were used for quantitative measurements (FIGS. 8 and 9). FIG. 9 shows an exemplary setup used to evaluate the performance of disclosed thin-film LSCs, illustrating the fiber-coupled light emitting diode (LED) emitting at 405 nm, an integrating sphere, a compact spectrometer, and square-shaped LSCs fabricated on substrates with different size (from 1 to 4 inch) with edges masked by a carbon tape. In addition, large-area rectangular pieces of commercial glass (30.5×91.4 cm²) were used to demonstrate real-life, window-size LSCs (FIG. 10). Regardless of the size, the fabricated devices comprising the disclosed

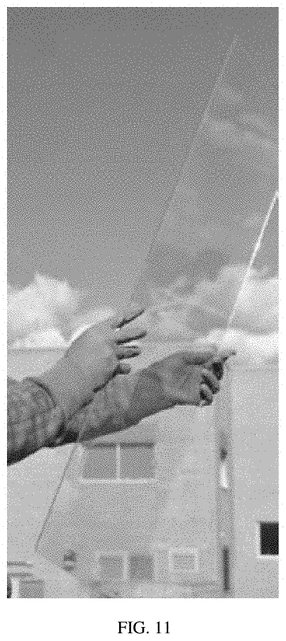

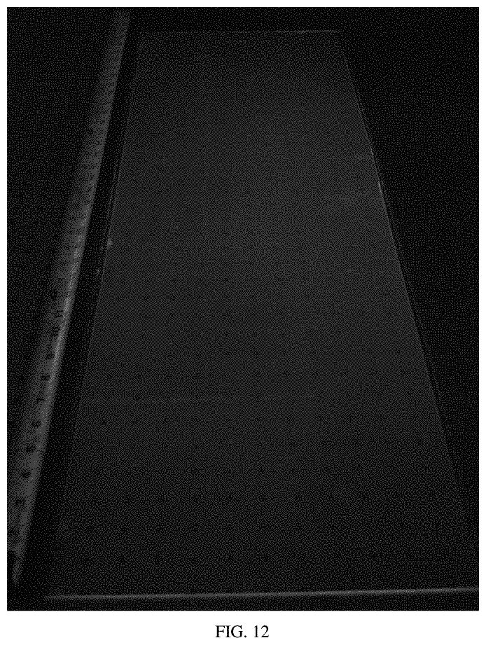

LSCs were highly luminescent and exhibited strong wave guiding effect as indicated by bright emission emerging from the slab edges under both sunlight illumination (FIG. 11) and weak ultraviolet (UV) illumination (FIG. 12).

### III. APPLICATIONS

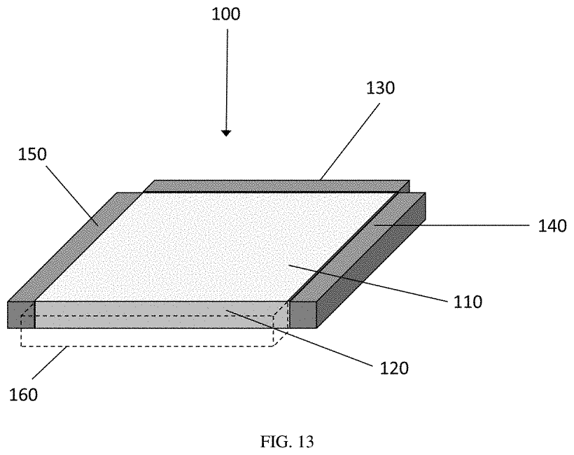

The disclosed compositions can be used in a variety of applications and devices, including but not limited to, solar cells and other applications comprising photovoltaic cells. One exemplary embodiment of a device is schematically shown in FIG. 13. With reference to FIG. 13, device 100 comprises a thin film LSC 110 comprising type-I giant quantum dots and a polymer, on substrate 120, such as a glass substrate. The device 100 also comprises photovoltaic cells, with the exemplary illustrated embodiment comprising four photovoltaic cells 130, 140, 150 and 160 (photovoltaic 160 is shown as transparent solely to enable substrate 120 to be visible). The composition receives incident light, such as from the sun, and some of that light is absorbed by the quantum dots. The photovoltaic cells then receive the luminescence emissions from the quantum dots.

In alternative embodiments, one, two or three of the photovoltaic cells, 130, 140, 150 and 160 may be replaced with reflectors and/or diffusers, such as white or silvered reflectors, reflectors coated with aluminum or other metals, or multilayer stacks of dielectric layers to form distributed Bragg reflectors. The function of the reflector is to reflect light back into the composition and towards the photovoltaic cell(s). In some embodiments, the reflectors are diffuse reflectors.

In other examples, the LSC 110 may not be surrounded by photovoltaic cells and/or reflectors. In these examples, any edge that does not have a reflector or photovoltaic cell may allow light to escape, thereby reducing the overall efficiency of the device.

In some embodiments, the LSC 110 and substrate 120 are transparent or semi-transparent, allowing the device to be used as a window. In such embodiments, the photovoltaic cells and reflectors and/or diffusers, if present, may be placed in the window frame. The window maybe of any suitable shape, such as a square or rectangle, circle, ellipse, triangle, pentagon, hexagon, octagon, arch, cross, star or an irregular shape. The window may be colored or colorless, tinted or not tinted, or a combination thereof. In some embodiments, the window is a two-way window, that is visible light can pass in both directions through the window pane. Alternatively, the window may be a ‘one-way’ window, thereby restricting the passage of visible light through the window. Ultraviolet and infrared light may still be able to penetrate the window. The window may be transparent in the visible and IR but strongly absorb UV light. In some embodiments, device 100 comprises a glass panel on top of, and optionally in contact with, LSC 110. The glass panel may act to protect LSC 110, such as from dirt and/or scratches. For example, the device may be a window comprising two or more panes of glass, such as a double-glazed window, and LSC 110 located between the two window panes, such as on an interior surface of one or more of the window panes. In some embodiments, the window is in a building or in a transportation device, such as an automobile, ship, train, airplane, or space vehicle, such as a rocket, shuttle, space station, wheeled space vehicle.

Alternatively, the disclosed LSCs may be used in any device where solar modules are, or could be, used. Typically, a solar module comprises a plurality of solar cells, where each solar cell is electrically connected to the module. This is a complex system, and such complexity typically results in higher manufacturing costs and makes replacing a faulty solar cell difficult and expensive. Disclosed embodiments of LSCs can be used in addition to the solar modules or to replace some or all of the solar cells in a solar module. LSCs have several advantages compared to solar cells. For example, they are typically less expensive to produce and do not need to be electrically connected to a device.

Furthermore, the coupled LSC-photovoltaic system is less sensitive to changes in the incident angle of solar radiation than a stand-alone photovoltaic. Specifically, since the LSC can absorb light incident onto both the front and the back side, it is more efficient in harvesting diffuse radiation than a standard photovoltaic under conditions of normal outdoor illumination. As a result, the efficiency of a photovoltaic averaged over all incident angles that occur during the daylight time is reduced to a greater degree compared to its peak efficiency for the normal incidence of sunlight compared to the LSC-photovoltaic system.

In some embodiments, a solar module comprising a plurality of solar cells can be replaced by one or more LSCs optically connected to one, or optionally more than one, photovoltaic cell, as described with reference to FIG. 13.

Applications where LSC can be used in addition to solar cells include any device that uses solar power to generate electricity and/or charge electrical storage devices. Examples include, but are not limited to, solar power generators, such as commercial solar power generators, or solar panels on houses; solar lamps; solar battery charging devices; solar transport devices, such as an automobile, ship, train, or airplane; or applications in space, such as a solar panel on a satellite, or a space transport vehicle including, but not limited to, a rocket, a shuttle, a space station, or an extraterrestrial wheeled vehicle such as the lunar roving vehicle or moon buggy.

### IV. EXAMPLES

### Materials

Cadmium oxide (CdO, 99.999%), zinc acetate (Zn(OAc)2, 99.99%), trioctylphosphine (TOP, 97%), elemental sulfur (S, 99.999%), and elemental selenium (Se, 99.999%) were purchased from Strem Chemicals. Myristic acid (MA, 99%), oleylamine (70%), oleic acid (90%), 1-octadecene (90%), 1-dodecanethiol (C₁₂SH, 98%), tetraethyl orthosilicate (TEOS, distilled before use), ammonium hydroxide solution (NH₄OH, 28.0-30.0 wt. % NH₃ basis, diluted to 20 wt. %), IGEPAL CO-520, anhydrous ethanol, cyclohexane, toluene and polyvinylpyrrolidone (PVP, average molecular weight 40,000) were purchased from Sigma-Aldrich. All chemicals were used without further purification, unless specified.

### Example 1

### Synthesis of Thick-Shell CdSe/Cd₁₋ₓZrₓS Giant Quantum Dots

The giant quantum dots were synthesized according to methods disclosed by Bae, W. K. et al. “Controlled Alloying of the CoreShell Interface in CdSe/CdS Quantum Dots for Suppression of Auger Recombination,” ACS Nano 7, 3411-3419 (2013) and Lim, J. et al. “Influence of Shell Thickness on the Performance of Light-Emitting Devices Based on CdSe/Zn_{1-X}Cd_{X}S Core/Shell Heterostructured Quantum Dots,” Advanced Materials 26, 8034-8040 (2014), both of which are incorporated herein by reference. Briefly, the zincblende CdSe cores with a 2-nm mean radius were prepared by rapidly injecting 0.5 mmol of trioctylphosphine selenium (TOPSe) into a mix of 1 mmol of cadmium myristate and 15 mL 1-octadecene. The fabricated CdSe cores were reacted without purification with 2 mL of 0.5 M cadmium oleate, 4 mL of 0.5 M zinc oleate, and 1.5 mL of 2 M n-trioctylphosphine/sulfur, repeatedly added at 300° C. This procedure resulted in the formation of the Cd₁₋ₓZnₓS alloyed shell with the thickness controlled by the duration of the reaction. The alloyed shell growth was monitored by taking reaction aliquots at different time intervals and analyzing them with TEM (for morphological information) and an inductively-coupled plasma atomic emission spectroscopy (for compositional information). In certain embodiments, the CdSe/Cd_{0.5}Zn_{0.5}S giant quantum dots (i.e. x was about 0.5) had a mean shell thickness of 4.0 nm and a core mean radius of 2 nm, resulting in an average quantum dot diameter of about 12 nm, with a quantum dot size dispersion of about 15% or less (FIGS. 2-4).

### Example 2

### Deposition of a Silica Shell

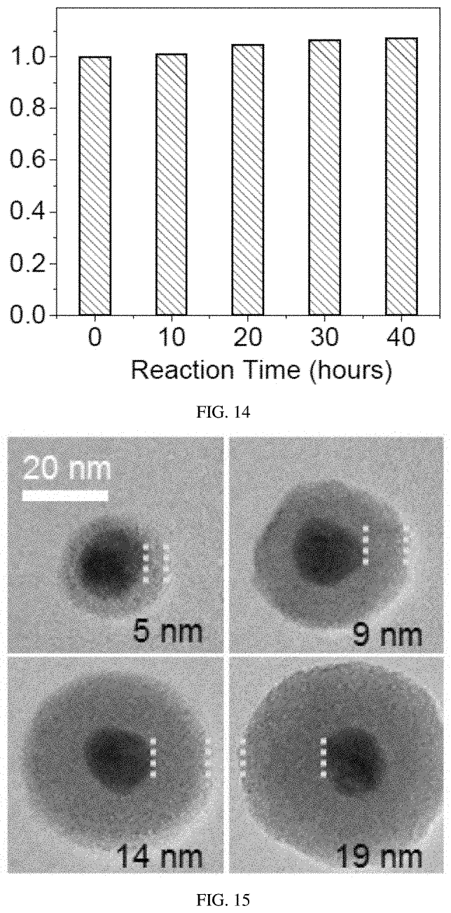

A micro-emulsion reaction was used to overcoat the synthesized quantum dots with silica shells. Briefly, 100 mL of cyclohexane as a solvent and 12 g of IGEPAL CO-520 as a surfactant were mixed at room temperature. 500 mg of giant quantum dots dispersed in 3 mL of toluene (concentration of the giant quantum dots was estimated to be ca. 2.7×10⁻⁸ mol/L) were introduced into the mixture, and then 2 mL (9 mmol) of TEOS was added. The reaction was initiated by adding 3 mL of ammonium hydroxide solution at the rate of 1 mL/minute, and then allowed to proceed for 40 hours. During the coating process, the photoluminescence intensity was monitored as a function of reaction time (FIG. 14). After purification, the silica-coated giant quantum dots could be readily dispersed in hydrophilic solvents such as water or ethanol. The above experimental conditions resulted in a silica-shell thickness of 5 nm. The shell thickness could be controlled by adjusting the amounts of giant quantum dots and TEOS.

### Example 3

### Evaluation of the Silica-Coated Quantum Dots

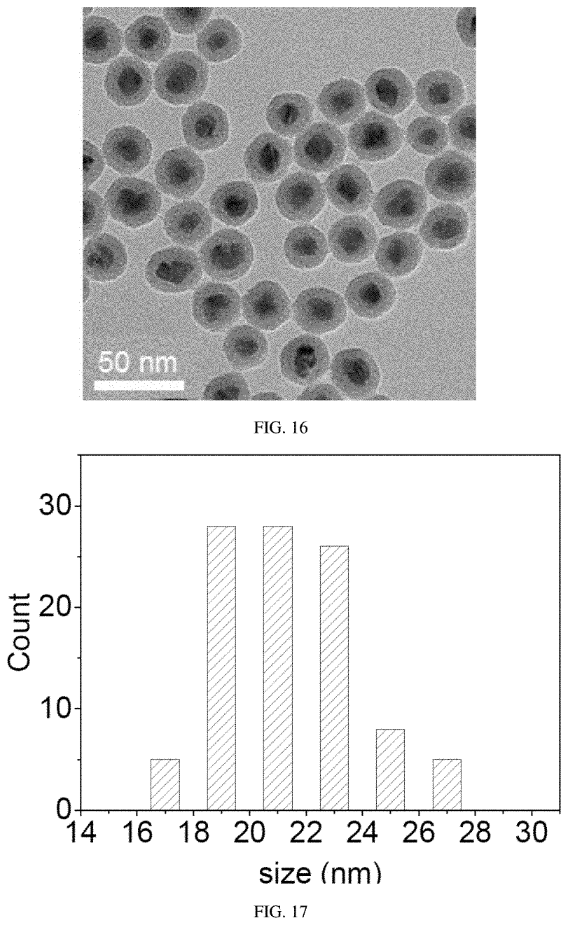

The silica layer thickness was varied by manipulating the amounts of quantum dots and TEOS in the synthesis. In certain disclosed embodiments, the shell thickness was from 5 nm to 19 nm (FIG. 15), and in particular embodiments, quantum dots overcoated with about 5 nm silica shells were used, which corresponded to an overall particle size of 22.5±2.3 nm (see FIGS. 16-17). TEM measurements indicated that in the majority of the composite particles (>99%) the quantum dot was located at the center of the structure (FIG. 16). Also, instances of multiple dots residing within the same silica shell or quantum dots located at the silica-shell surface were only rarely, if ever, observed. This was a substantial improvement over previously reported silica-coated dots. This improvement may be due, at least in part, to the relatively large size of the “giant” type-I quantum dots, which might inhibit or substantially prevent incorporation of multiple quantum dots into the same micelle.

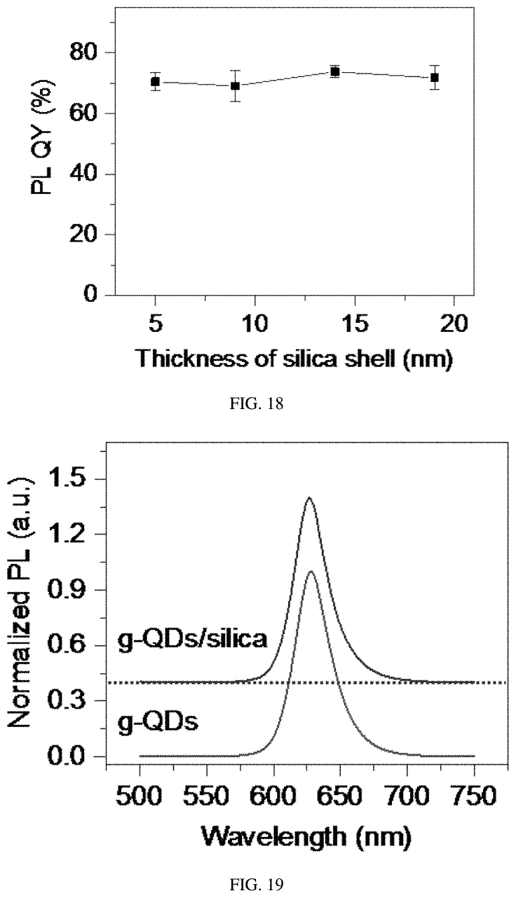

Next, the effect of silica coating on spectroscopic properties of the quantum dots was evaluated. Solution-based quantum dot samples were used. Uncoated quantum dots were dissolved in toluene, and silica-coated quantum dots were dissolved in ethanol. The results showed that the growth of silica shells around the disclosed thick-shell type-I giant quantum dots did not lead to any losses in the photoluminescence quantum yield. As illustrated in FIG. 14, as the silica shell grew, the photoluminescence intensity, monitored as a function of reaction time, remained virtually unchanged compared to the first, “time-zero” data point corresponding to a pristine giant quantum dot sample before adding any tetraethyl orthosilicate (TEOS) or ammonium. Thus, upon overcoating with silica the original photoluminescence quantum yield of the quantum dots before overcoating with silica of about 70% was preserved. FIG. 18 shows that this was observed for all of the studied shell thicknesses from 5 nm to 19 nm. This is in sharp contrast to previous reports where the deposition of silica shells resulted in a photoluminescence quantum yield drop of at least 60%.

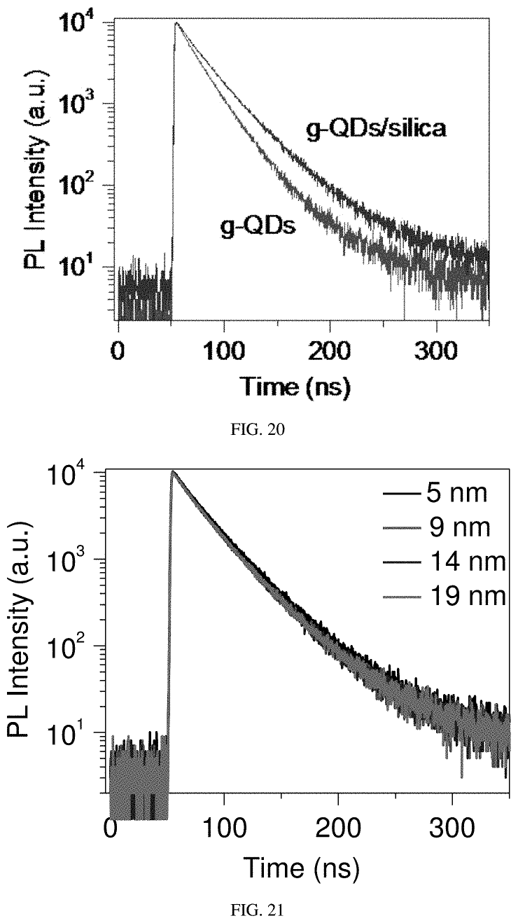

Further, there were no changes detected either in the photoluminescence peak position, or the photoluminescence spectral profile upon quantum dot encapsulation into a silica shell (FIG. 19). The time-resolved photoluminescence measurements (FIG. 20) indicated that the photoluminescence lifetime (lie decay constant) increased from 19.5 ns to 26.2 ns after silica-shell deposition. Without being bound to a particular theory, the difference could be due to the differences in the dielectric constants (c) of toluene (ε=1.76; used with uncoated dots) and ethanol (ε=2.24; used with silica-coated dots), as elaborated in Example 4). Furthermore, as illustrated in FIG. 21, the photoluminescence dynamics were not sensitive to shell thickness. All of these observations indicated that the silica shell did not perturb the emitting state of the disclosed thick-shell type-I giant quantum dots.

The deposition of a silica shell also helped suppress photoluminescence losses in dense quantum dot assemblies such as quantum dot clusters that are often formed during the preparation of quantum dot/polymer composites. In the case of quantum dot clustering, a photo-injected exciton can undergo multiple steps of energy transfer driven by near-field dipole-dipole interactions between proximal quantum dots. Because of this process, the exciton can sample nonradiative centers in multiple quantum dots, leading to a decrease of the photoluminescence quantum yield compared to the case of dilute solutions where quantum dots are isolated from each other and the exciton samples just one nonradiative center.

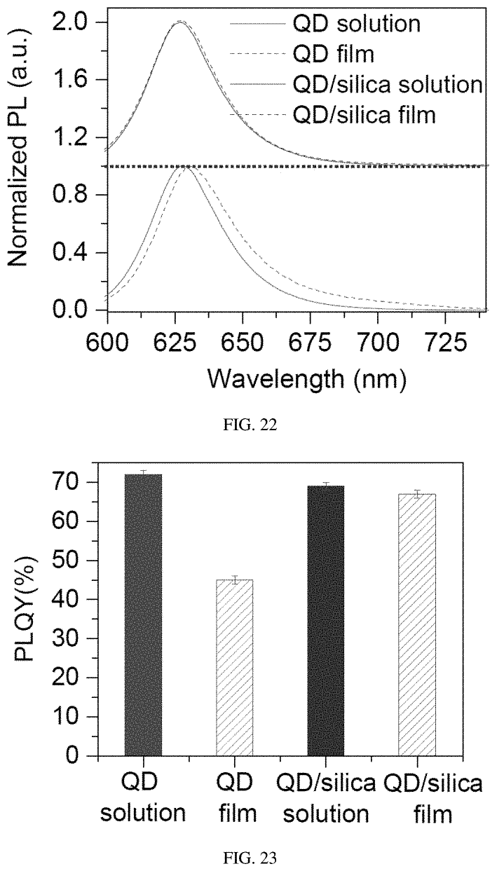

To investigate the effect of silica overcoating on photoluminescence quenching due to energy transfer, close-packed, spin-coated films of the quantum dots without and with silica shells (5 nm shell thickness) were studied. The energy transfer in samples of Cd_{0.5}Zn_{0.5}S giant quantum dots was expected to be considerably suppressed compared to core-only or thin-shell samples, due to the presence of the thick shells that increased the separation between emitting CdSe cores. Such suppression has been previously documented. However, in films prepared according to the disclosed embodiments and comprising the disclosed silica coated type-I quantum dots with a 5 nm shell thickness, the photoluminescence spectrum was indistinguishable from that of the solution sample (FIG. 22, top), indicating a substantially complete suppression of energy transfer. This was in contrast to samples prepared without silica shells, which showed a small but measurable redshift (3 nm or 10 meV) of the photoluminescence peak of the film versus that in the solution sample, demonstrating that energy transfer was still occurring (FIG. 22, bottom). This redshift was indicative of exciton migration from smaller to large dots, as has been observed in numerous previously studies starting from the first observation of this effect in quantum dot films.

The effect of the silica overcoating was confirmed by the evaluation of the photoluminescence efficiencies measured by an integrating sphere method (see Example 6). Based on these measurements, the photoluminescence quantum yield of the CdSe/Cd_{0.5}Zn_{0.5}S giant quantum dots without silica coating was quenched by about 38% in close-packed films compared to quantum dot solutions (FIG. 23). In contrast, the emission efficiency of films of silica-coated quantum dots was virtually the same as that of quantum dots in solution, which is a direct result of suppressed energy transfer (FIG. 23).

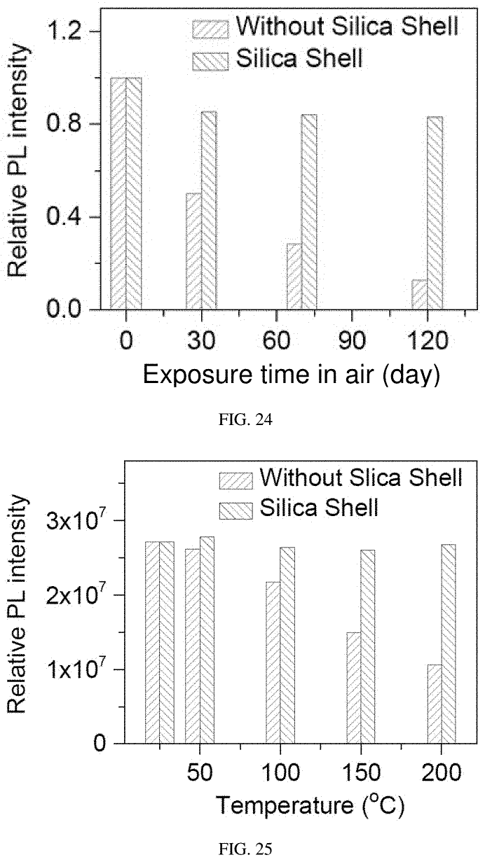

An important benefit of silica overcoating is a significant improvement in the long-term photo- and thermal stability of the quantum dots. In tests of photo-stability, spin-coated films of silica-coated (5 nm shell thickness) and uncoated quantum dots were exposed to air under room lights, and their photoluminescence intensity was monitored over four months. The film of uncoated quantum dots showed a monotonic decrease in the photoluminescence intensity with time and after 4 months it retained only about 13% of the original photoluminescence quantum yield (FIG. 24). In contrast, the film of silica-coated quantum dots showed about 15% photoluminescence intensity loss during the first month and then exhibited a nearly constant photoluminescence intensity (FIG. 24), such that 85% of the original photoluminescence quantum yield was preserved at the end of the four-month test.

Silica-coated QDs have also shown a high level of stability in “accelerated-aging” tests conducted using high-intensity excitation from a 462-nm light emitting diode (LED). In these measurements, the absorbed power was 1.48 W/cm², which corresponded to the acceleration factor of 247 when compared to the absorbed solar power. To protect the silica-coated QD film from direct exposure to oxygen, the film was loaded into an airtight cuvette under N₂ atmosphere; in practical devices, such protection can be accomplished by borrowing procedures, for example, from the organic-LED display technology. The measurements indicated virtually no changes in the photoluminescence quantum yield up to about 100 hours of testing, and then only a slight decrease (by about 9%) within the next 100 hours. Given the 247 acceleration factor, the 200 hours of accelerated aging translated into about 5.6 years of continuous exposure to direct sunlight or about 14 years of outdoor lifetime if one accounts for a standard day-night cycle. The results of this test indicated that the stability of the quantum dot samples should satisfy the stability requirements for commercial photovoltaic systems.

In studies of thermal stability, spin-coated quantum dot films were placed into an oven preheated to a desired temperature (50-200° C.) and then heated for 30 minutes in air. For temperatures up to 50° C., both silica-coated (5 nm shell thickness) and uncoated quantum dots did not show any signatures of photoluminescence degradation (FIG. 25). However, after treatment at 100° C., the uncoated quantum dots lost about 20% of the original photoluminescence quantum yield, while the photoluminescence efficiency of silica-coated quantum dots remained intact. The treatment at higher temperatures resulted in a progressively stronger photoluminescence quenching in films of uncoated quantum dots and the photoluminescence loss reached about 60% after the 200° C. treatment. On the other hand, no appreciable changes in the photoluminescence efficiency were observed for silica-coated dots for temperature up to 200° C. (FIG. 25). The remarkable thermal and long-term photo-stability of the disclosed silica-coated, type-I giant quantum dots indicated that these nanostructures were suitable not only for proof-of-principle device demonstrations but also for applications in real-life technologies where material stability is one of the key commercial requirements.

### Example 4

### Effect of Dielectric Environment of Photoluminescence Lifetimes

Time-resolved photoluminescence measurements (FIG. 20) indicated that the 1/e photoluminescence decay time in the case of the silica-coated giant quantum dots was longer than that of the uncoated giant quantum dot sample (26.2 ns vs. 19.5 ns). However, the uncoated giant quantum dots used in this study were dissolved in toluene, while the silica-coated samples were prepared in ethanol.

The radiative decay rate, kᵣ, of a quantum dot with the high-frequency dielectric constant C_{Q}D placed in a medium with the high-frequency dielectric constant εₛ can be determined from the expression:

$${k}_{r} = \frac{{e}^{2}}{2 {πɛ}_{0} {m}_{e} {c}^{3}} ϕ \sqrt{{ɛ}_{s}} {\vert {f}_{LF} \vert}^{2} {ω}^{2} \qquad ( E1 )$$

where, φ is the oscillator strength of the quantum dot optical transition, ω is the emission frequency, and f_{LF} is the local field factor. The local-field factor can be calculated from:

$${f}_{LF} = \frac{3 {ɛ}_{s}}{2 {ɛ}_{s + {ɛ}_{QD}}} .$$

The dielectric constant of silica shell ε_{silica} is 2.18, which is very close to the dielectric constant of toluene (ε_{s,toluene}=2.24). If one assumes that in the case of silica-coated quantum dots, the dielectric constant of the external medium is equal to that of silica, then the ratio of radiative decay rates between coated and uncoated samples would be 0.95. This is, however, inconsistent with the observations that indicate a stronger difference.

Since the silica shell is only a few-nanometer thick and is also porous, it is reasonable to assume that the dielectric properties of the environment experienced by the giant quantum dots are defined not by silica but rather ethanol. The effect of silica can, in principle, be accounted for within the effective medium theory. However, considering that the volume fraction of silica in the silica/ethanol medium is small, the effective dielectric constant should approach that of ethanol. This leads to the conclusion that the observed difference in photoluminescence lifetimes between the silica-coated and uncoated giant quantum dots was primarily due the difference in dielectric constants of the solvents used to prepare the studied samples.

For ethanol and toluene, εₛ is 1.76 and 2.24, respectively. For giant quantum dots, ε_{QD} is approximately 7.69. Based on these values,

$$\frac{{k}_{r . ethanol}}{{k}_{r . toluene}} = \sqrt{\frac{{ɛ}_{s . ethanol}}{{ɛ}_{s . toluene}}} \times {\vert \frac{{f}_{LF . ethanol}}{{f}_{LF . toluene}} \vert}^{2} = 0.71 .$$

The calculated ratio is very close to the ratio of the measured photoluminescence decay rates (19.5/26.2=0.74), confirming the assessment that the observed difference in photoluminescence lifetimes is linked to the difference in the dielectric constants of the solvents. This further indicates that encapsulation of the giant quantum dots into thin silica shells does not appreciably modify the dielectric environment “seen” by the quantum dots.

### Example 5

### Fabrication of Quantum Dot/Polymer Films

Silica-coated giant quantum dots dispersed in ethanol (40 mg/mL; the weight of silica shell was not included) were mixed with a PVP solution (0.6 g/mL in ethanol) to form a homogenous giant quantum dot/polymer slurry of appropriate viscosity (2-100 Pa s). In order to obtain a high-quality film, the slurry was centrifuged to remove any bubbles. The quantum dot/PVP films were deposited using either a manual version of a doctor-blade technique or a commercial doctor-blade apparatus (MTI Corporation, MSK-AFA-L800) to produce a film comprising giant quantum dots dispersed in the polymer. The gap between the blade and the substrate surface was 100 μm for all fabricated devices. The blade was translated over the substrate at a speed of 200 mm/s. The film was exposed to air at room temperature and allowed to dry for 10 minutes before measurements were taken.

### Example 6

### Evaluation of LSC Performance

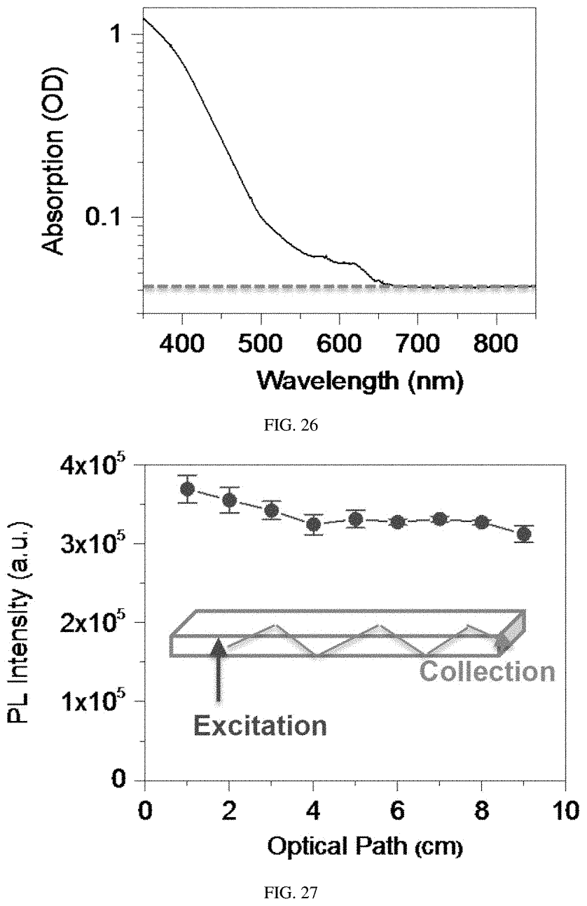

A typical signature of optical scattering is a low-energy tail in absorption spectra extending past the band edge into the intra-gap region. However, in disclosed embodiments, the absorption onset was extremely sharp (FIG. 26), and at lower energies the absorption spectrum exhibited only a small constant offset (optical density of about 0.04) due to light reflection from the front and back LSC surfaces (about 8% reflectivity).

A considerable reduction in the optical losses of disclosed embodiments, compared to the optical losses of all-polymer devices, was also indicated by studies of photoluminescence attenuation as a function of propagation length in the LSC waveguide (FIG. 27). In previous measurements, LSCs made by bulk polymerization of CdSe/CdS giant quantum dots/PMMA composites exhibited a photoluminescence loss over a distance of 10 cm of about 50%. This loss was assumed to be primarily to scattering within the polymer matrix. However, in disclosed embodiments of a device comprising the disclosed thin-film LSC, the optical loss was only about 15% for the same propagation distance of 10 cm (FIG. 27). This was a significant improvement over the all-polymer LSC device, and indicated a suppression of light scattering.

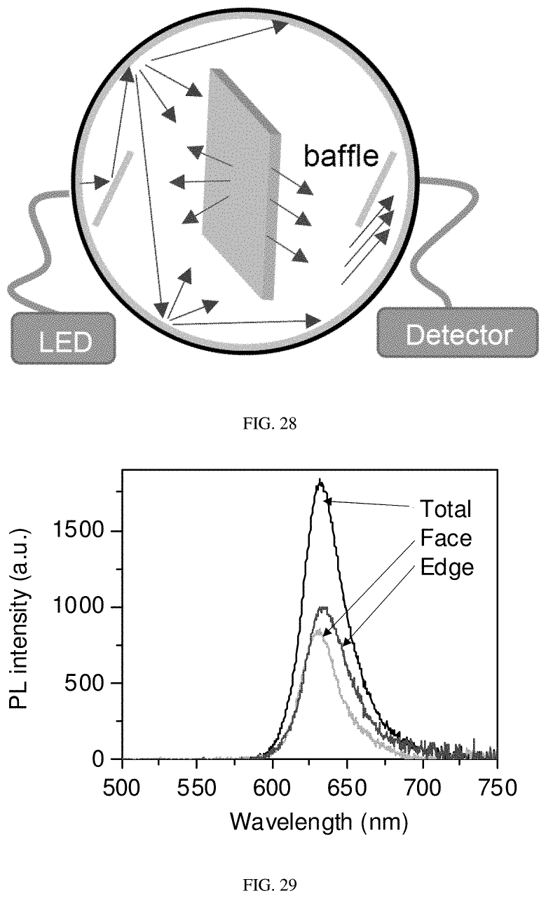

The reduced scattering losses resulted in a considerable improvement in performance of the disclosed thin-film devices compared to previously demonstrated LSCs based on similar thick-shell giant quantum dot structures. To quantify the performance of the disclosed fabricated LSCs, a fiber-in-fiber-out, integrating-sphere setup was used (FIGS. 9 and 28). The approach was similar to that utilized in measurements of photoluminescence quantum yields of thin-films and powder samples. The excitation source was a 405 nm light emitting diode (LED) coupled to the input fiber. An LSC device was shielded from direct exposure to incident LED light by a baffle, which led to diffuse illumination of the LSC (FIG. 28). This is similar to a real-life situation of illumination with ambient sunlight. The second baffle shielded the output of the integrating sphere to eliminate errors arising from a considerable difference in angular distributions of light emitted from the LSC edges and the light leaving the LSC through the escape cone. All studied LSCs had a reflectance of about 4% and an optical density of 0.6 at 405 nm, which corresponded to a transmission coefficient (T ) of 25%. Due to constraints imposed by the size of the integrating sphere, the largest LSCs tested in these measurements were characterized by L=10.2 cm.

Several characteristics were used to quantify LSC performance. The photoluminescence quantum yield of an LSC (η_{PL,LSC}) was defined as the ratio between the total number of photons emitted by the LSC and number of photons absorbed by it. Importantly, the photoluminescence quantum yield introduced in this way may differ from the “intrinsic” photoluminescence quantum yield of the quantum dots (η_{PL}) measured for dilute quantum dot solutions due to LSC-specific processes such as re-absorption of guided light followed by nonradiative recombination. The edge-emission efficiency (η_{edge}) was defined as the ratio between the number of photons emitted from the LSC edges and the total number of photons emitted from all LSC surfaces. For a waveguide with the refractive index of 1.5, the maximum value of η_{edge} is about 75%; the remaining 25% of photons leave the LSC through a so-called “escape cone” defined by the angle of total internal reflection. In a nonideal case, the value of η_{edge} is reduced due to nonradiative recombination in LSC fluorophores as well as additional losses through the escape cone following re-absorption/re-emission events and scattering of guided light in a polymer matrix and an underlying substrate. The internal quantum efficiency (ηᵢₙₜ) or collection efficiency (η_{col}), was defined as the ratio of the number of photons collected at the LSCs edges and the number of incident photons absorbed by the LSC. It was calculated from ηᵢₙₜ=η_{col}=η_{PL,LSC}η_{edge}. The external quantum efficiency (ηₑₓₜ) was obtained by multiplying ηᵢₙₜ by the LSC absorptance, η_{abs}=(1−R)(1-10^{-OD}), which yields ηₑₓₜ=η_{abs}ηᵢₙₜ=(1−R)(1-10^{-OD}) η_{PL,LSC}η_{edge}; R and OD are, respectively, the reflectance and the optical density of the LSC at the incident-light wavelength. Finally, the concentration factor (C) was defined as the ratio of flux densities of outcoupled and incident radiation. This quantity can be thought of as an effective enlargement (or contraction) factor of an area of a photovoltaic device when it is coupled to an LSC. The C-factor is related to ηₑₓₜ by C=Gηₑₓₜ, where G is the geometric gain factor (the ratio of the areas of the front surface and device edges), which for the studied devices can be found from G=L/[4(D+d)] (FIG. 8).

The measurements began by placing an LSC into the integrating sphere, from which the total number of photons emitted by the device was determined. This quantity is proportional to η_{PL,LSC}. Next, the same measurement was repeated after masking the LSC edges with a black tape, which gave the number of photons lost by the LSC through the escape cone. FIG. 29 shows the photoluminescence spectra of the 5.1×5.1 cm² device (26 cm² front-face area) obtained from these two measurements. The total photoluminescence intensity of the unmasked LSC was much stronger than that of the masked one, indicating a high wave-guiding efficiency of the device. A slight redshift of the edge photoluminescence (by 4 nm) compared to the face photoluminescence was a result of reabsorption/reemission events that affect wave-guided light. By taking the difference between the unmasked and masked-device spectra, the spectrum of “useful” emission emerging from the LSC edges was obtained. η_{edge} was calculated by dividing the area of this spectrum by that of the total emission.

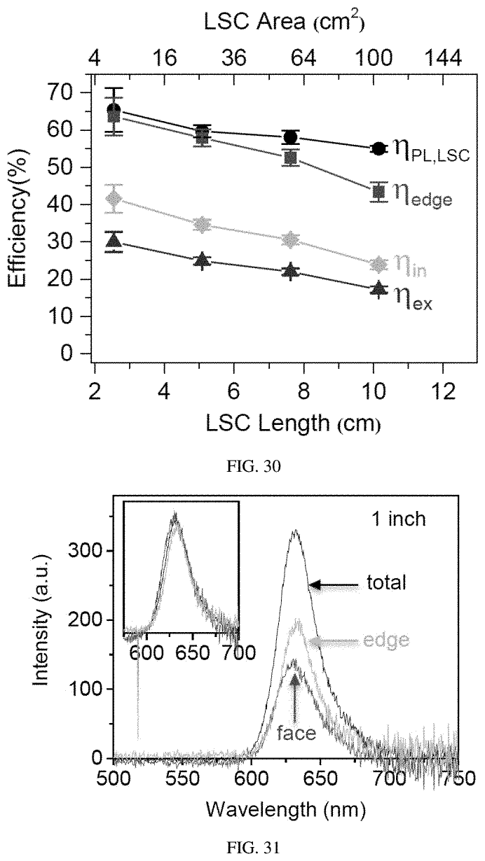

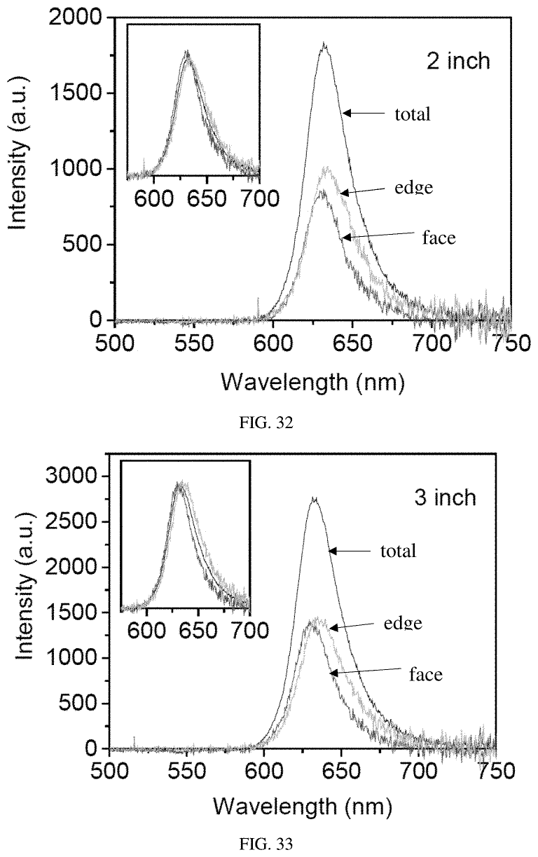

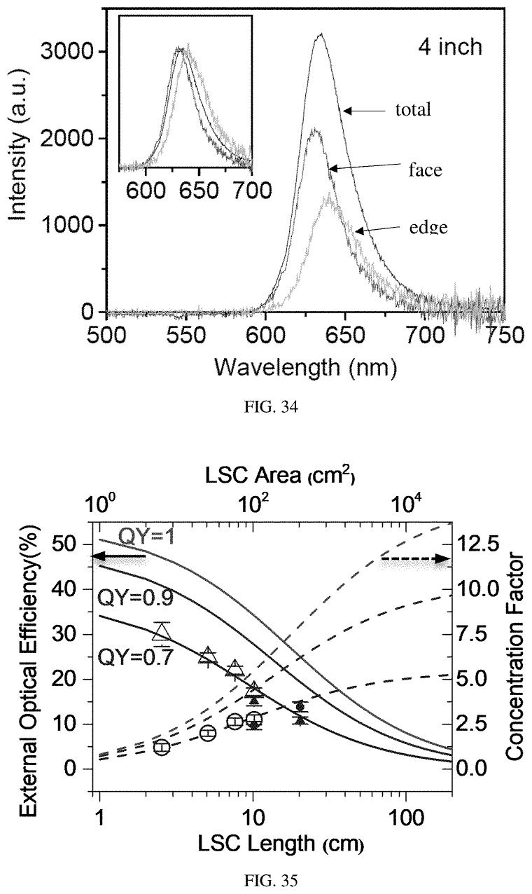

The η_{PL,LSC} and η_{edge} of the LSCs with the same quantum dot/PVP layer thickness and optical density but different side lengths (L) were plotted in FIG. 30. With respect to FIG. 30, the black circles represent the LSC photoluminescence quantum yield (η_{PL,LSC}) and the edge emission efficiency (η_{edge}; red squares) of fabricated devices. The product of η_{PL,LSC} and η_{edge} gives the internal optical efficiency of the LSC (ηᵢₙₜ, green diamonds). Multiplied by the LSC absorptance, ηᵢₙₜ is converted into the external optical efficiency (ηₑₓ, blue triangles). Both the η_{PL,LSC} and η_{edge} of the LSCs decreased with increasing L. Specifically, η_{PL,LSC} dropped from 65.4% to 55.0% (about 16% relative difference) when the length was increased from 2.54 to 10.16 cm (1 to 4 inches) (FIG. 30). This was mostly a result of increasing losses due to reabsorption followed by nonradiative recombination. Another manifestation of re-absorption is the redshift of edge-detected photoluminescence versus the photoluminescence escaping through the front and back LSC faces, which increases with the device size (FIGS. 29 and 31-34). FIGS. 31-34 provide the relative photoluminescence intensities of LSC of different sizes. The edge emission spectra show a redshift with regard to the spectrum of face emission, which is a result of reabsorption/reemission effects experienced by waveguided light. As expected, this shift increases with increasing the device dimensions. The insets show the same spectra in a normalized form.

Based on the “intrinsic” photoluminescence quantum yield derived from the solution-sample measurements (η_{PL}=69.3%), and the above measurements of quantum yields of the LSCs, the average number of reabsorption events experienced by the first-generation photoluminescence photon during its propagation in the wave guide (N_{re-abs}) was estimated. Following each re-absorption event, the probability of recovering the photon was defined by η_{PL}. Hence, η_{PL,LSC}=(η_{PL})^{1+Nre-abs}, or N_{re-abs}=[ln(η_{PL,LSC})/ln(η_{PL})−1]. Using this expression, N_{re-abs} was approximately 0.16, 0.38, 0.48, and 0.63, for devices with L=2.54, 5.08, 7.62, and 10.16 cm, respectively. The scaling of N_{re-abs} (1.0:2.4:3.0:3.9) closely followed that of the LSC sizes (1:2:3:4), indicating the direct relationship between N_{re-abs} and the lateral dimensions of the device. This confirmed that the main loss mechanisms in these devices was not scattering within the waveguide but weak re-absorption by the quantum dots.

The efficiency of edge emission (η_{edge}) showed a faster drop with increasing device size than η_{PL,LSC}. Specifically, η_{edge} decreased from 63.6% to 43.4% (32% relative drop), as the device size increases from 2.54 to 10.16 cm (FIG. 30). Without being bound to a particular theory, this may be due to qₑd_{ge} being affected by “randomization” of photon propagation direction during each re-absorption or scattering event, in addition to nonradiative losses, which leads to the addition loss due to emission into the escape cone. The internal optical efficiency (ηᵢₙₜ), showed the same LSC-size dependence as η_{edge}, and decreased from 41.6% to 23.9% as L increased from 2.54 to 10.16 cm (FIG. 30). Accounting for the percentage of absorbed photons (about 72%) at the excitation wavelength, the external optical efficiency (ηₑₓₜ) for the smallest and the largest studied devices were 30% and 17%, respectively (FIG. 30). Further, taking into account the geometric gain factor (varied from 4 to 16), the optical concentration factors achieved with these devices varied from 1.2 to 2.7.

Next, these measurements were analyzed using a recently developed analytical model of planar LSCs, described in Example 7, which was benchmarked against commonly used Monte Carlo ray-tracing simulations, and further validated by experiments on quantum dot-solution-based devices. The analytical model accurately described the results of measurements for ηₑₓₜ and C when it was applied to the fabricated LSCs (FIG. 35; compare symbols (experiment) and lines (calculations)). This suggested that this model could be used for evaluating the expected performance of larger devices that could not be directly measured in the experimental set-up due to the size limitations.

Based on the calculations with the presently available quantum dots and the same device architecture as in the present study, high external efficiencies of more than 10% should be maintained for LSC lengths of at least 25 cm, which should also allow for pushing the concentration factor to more than 4. Even with a large, window-size LSC (L=100 cm), ηₑₓₜ is still calculated to be about 3% (C of about 5). For comparison, the 22 cm devices fabricated using similar, CdSe/CdS thick-shell quantum dots and bulk-polymerized PMMA exhibited ηₑₓₜ of only 1%, limited primarily by scattering losses in the polymer waveguide.

A further boost in the LSC performance could be obtained by improving the photoluminescence quantum yield of the quantum dots. As illustrated in FIG. 35, increasing ηₑₓₜ to 90%, would lead to almost doubling the external efficiency (ηₑₓₜ of about 5.8%) of the 100-cm devices. A further increase to 8% should be possible with the quantum dots approaching the ideal 100% limit of photoluminescence efficiency.

### Conclusion

Disclosed herein are embodiments of large-area (up to ca. 90×30 cm²), high-performance, thin-film LSCs that were based on thick-shell CdSe/Cd₁₋ₓZnₓS quantum dots, encapsulated into silica shells, and deposited onto glass slabs using a doctor-blade technique. The quantum dot optical spectra were tailored to spectrally separate the photoluminescence band from the onset of strong absorption, which allowed losses due to self-absorption to be minimized even in devices with large, such as tens-of-cm, sizes. An oil-in-water micro-emulsion reaction was employed to deposit a silica shell, which was sufficiently mild to avoid distortion of quantum dot photoluminescence spectra or dynamics, and to avoid any noticeable loss of the photoluminescence quantum yield (70% in the present study). Silica-coated quantum dots and PVP formed a uniform dispersion in ethanol and the resulting slurry was easily processed, either manually or by a doctor-blade machine, into a uniform and highly emissive film on top of glass slabs of arbitrary dimensions including commercial windows. The use of the silica coating significantly improved the compatibility of the quantum dots with a polymer matrix and greatly enhanced their stability, as verified by a four-month photo-exposure test along with tests for thermal stability at temperatures up to 200° C.

In quantitative studies of the LSC performance, square-shaped devices were investigated, with the side length from 2.54 to 10.16 cm, limited only by the size of the integrating sphere set-up. Even in the largest device, losses due to scattering at optical imperfections could not be detected, indicating an improvement over all-polymer waveguides, where light scattering is a typical problem. Despite being partially transparent (T=25%), the fabricated LSCs showed a high external optical efficiency, which varied from 29% in the 2.54 cm device, to 17% in the 10.16 cm structure. Projections using a planar-LSC model suggested that more than 10% external efficiencies are expected to be maintained up to about 30 cm LSC sizes, and even very large 100 cm devices should still show rᵢₑₓₜ of about 3%. These characteristics can be further improved by increasing the quantum dot photoluminescence quantum yield.

The doctor-blade thin-film fabrication technique disclosed herein is highly versatile and can be applied to any mutually compatible quantum dot/polymer pairs including both polar and nonpolar systems. This method does not require any special substrates and can applied to standard window glass or any other flat surface made of an arbitrary material. Importantly, in the case of the deterioration of the quantum dot-LSC layer, the substrate can be easily re-used by replacing an old quantum dot-film with a new one. The use of this inexpensive and highly scalable technique represents a practical route to real-life applications of quantum dot-LSCs in both semitransparent solar windows and high-concentration collectors of sunlight supplementing existing photovoltaic cells.

### Example 7

### Analytic Model for the Calculation of LSC Efficiencies

The analytic model for calculating optical efficiencies and concentration factors of planar LSCs was disclosed by Klimov, V. I., et al. “Quality Factor of Luminescent Solar Concentrators and Practical Concentration Limits Attainable with Semiconductor Quantum Dots,” ACS Pho., submitted (2016), incorporated herein by reference. Briefly, the internal optical efficiency (ηᵢₙ) or the collection efficiency (η_{col}) is defined as: η_{col}=η_{PL}ηₜᵣₐₚη_{wg}, where η_{PL} is the “true” photoluminescence quantum yield of quantum dots measured in dilute solutions, ηₜᵣₐₚₛ is the efficiency of light trapping into waveguide modes (75% for a waveguide with the refractive index n=1.5) and η_{wg} is the waveguiding efficiency defined as a fraction of the first-generation, waveguide-trapped photoluminescence photons that eventually reach the LSC edges.

For the situation when every re-absorption event is followed by nonradiative recombination, η_{wg} can be described by η_{wg}⁽¹⁾=1/(1°βα₂L), where α₂ is the absorption coefficient of the LSC at the emission wavelength and L is its length. Based on numerical calculations by Weber and Lambe (Appl. Opt. 15, 2299-2300 (1976)), β can be approximated by a constant equal to 1.4, which provides ±15% accuracy in describing the exact solution for α₂L up to 20. The corresponding collection efficiency, η_{col}⁽¹⁾=η_{PL}ηₜᵣₐₚη_{wg}⁽¹⁾, accounts only for the first-generation photoluminescence photons produced following the absorption of the original incident light. In reality, absorption of waveguided radiation is followed by reemission, which increases the overall collection efficiency and can be accounted for by summing the contributions from the second, third, etc. reemission events.

To account for the second-generation of reemitted photons (collection efficiency η_{col}⁽²⁾, the first generation collection efficiency η_{col}⁽¹⁾ is applied to the fraction of the photons (1−η_{wg}⁽¹⁾) removed from the propagating modes by the first reabsorption event. This leads to η_{col}⁽²⁾=η_{PL}ηₜᵣₐₚ(1−η_{wg}⁽¹⁾)η_{col}⁽¹⁾. Similarly, η_{col}⁽³⁾=[η_{PL}ηₜᵣₐₚ(1−η_{wg}⁽¹⁾)]²η_{col}⁽¹⁾, η_{col}⁽⁴⁾=[η_{PL}ηₜᵣₐₚ(1−η_{wg}⁽¹⁾)]³η_{col}⁽¹⁾, etc. The total collection efficiency is the sum of contributions due to all photon generations, which yields: η_{col}=[1−η_{PL}ηₜᵣₐₚ(1−η_{wg}⁽¹⁾)]⁻¹η_{col}⁽¹⁾. Using the expression for η_{wg}⁽¹⁾, one can obtain:

η_{col}=η_{PL}ηₜᵣₐₚ[1+βα₂L(1−η_{PL}ηₜᵣₐₚ)]⁻¹ (E2).

Using equation E2, one can calculate the external optical efficiency from ηₑₓ=η_{col}η_{abs}. Here η_{abs}, is the LSC absorbance, which can be found from η_{abs}=(1−R)(1−e^{-a}1^{d}), where R is the reflection coefficient at the excitation wavelength (about 4% in certain disclosed cases), α₁ is the absorption coefficient of the LSC at the excitation wavelength, and d is the LSC thickness. The final expression can be presented as

$${η}_{ex} = \frac{( 1 - R ) ( 1 - {e}^{- {α}_{1} d} ) {η}_{PL} {η}_{trap}}{1 + {βα}_{2} L ( 1 - {η}_{PL} {η}_{trap} )} . \qquad ( E3 )$$

Klimov et al. benchmarked equation E3 against numerical Monte Carlo (MC) ray-tracing simulations and also directly compared it to experimental measurements on LSCs based on quantum dot solutions. It was found that the analytic model provided an excellent agreement with both MC results and experimental data over a wide range of LSC parameters. This suggested that it should also be applicable to the LSCs studied in the present work.

However, it was found that when the parameters of the disclosed LSCs α₂) were used in equation E2, the model considerably underestimated the results of the measurements for η_{PL}. This discrepancy related to the difference in geometries of devices considered in Klimov et al. and those in the present disclosure. The original model was developed for a homogeneous distribution of fluorophores across the LSC thickness. In the disclosed, layered LSCs, however, the fluorophores are concentrated in the top thin layer (thickness d) deposited onto a transparent glass slab (thickness D), which apparently affects the overall LSC efficiency. To account for this difference in geometries, an effective absorption coefficient for propagating light was introduced,

a_{2,eff}=a₁[d/(D+d)] (E4),

and it was further assumed that the overall performance of the layered LSC was equivalent to that of the uniform LSC whose absorption coefficient was replaced with the effective (reduced) value calculated according to equation E4. After applying this scaling procedure, a very close correspondence between the calculations and the measurements was obtained (FIG. 35). This validated the use of the adjusted theory of Klimov et al. for evaluating the expected performance of the disclosed layered LSCs for the situations of higher quantum dot photoluminescence quantum yield and larger device sizes.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1. A coated type-I quantum dot comprising a core and a shell, and a silica coating.

2-3. (canceled)

4. The quantum dot of claim 1, wherein:
the core is CdSe, CdTe, Si, CdSe₁₋ₓSₓ, Cd₁₋ₓZnₓSe, InAs, Cd₃P₂, CuFeS₂, InₓGa₁₋ₓP, CuInSe₂₍₁₋ₓ₎S₂ₓ, AgInSe₂₍₁₋ₓ₎S₂ₓ, (ZnS)ₓ(CuInS₂)₁₋ₓ, or (ZnSe)x(CuInSe₂)₁₋ₓ and x is from 0 to 1;
the shell is Cd₁₋ₓZnₓS, Cd₁₋ₓZnₓSe, ZnSe_{1-y}S_{y}, Cd₁₋ₓZnₓSe_{1-y}S_{y}, CdSe, InP, CuInSe₂₍₁₋ₓ₎S₂ₓ, AgInSe₂₍₁₋ₓ₎S₂ₓ, or GaP_{1-y}N_{y}, and x is from 0 to 1 and y is from 0 to 1;
or a combination thereof.

5. (canceled)

6. The quantum dot of claim 1, wherein the quantum dot has a core/shell structure selected from CdSe/Cd₁₋ₓZnₓS, CdSe/Cd₁₋ₓZnₓSe, CdSe/ZnSe_{1-y}S_{y}, CdSe/Cd₁₋ₓZnₓSe_{1-y}S_{y}, CdTe/ZnSe_{1-y}S_{y}, CdTe/Cd₁₋ₓZnₓSe_{1-y}S_{y}, CdSe₁₋ₓSₓ/Cd_{1-y}Zn_{y}S, Cd₁₋ₓZnₓSe/ZnSe_{1-y}S_{y}, InAs/CdSe, InAs/InP, InAs/Cd₁₋ₓZnₓSe_{1-y}S_{y}, Cd₃P₂/ZnSe_{1-y}S_{y}, InₓGa₁₋ₓP/ZnSe_{1-y}S_{y}, InₓGa₁₋ₓP/GaP_{1-y}N_{y}, CuInSe₂₍₁₋ₓ₎S₂ₓ/ZnSe_{1-y}S_{y}, AgInSe₂₍₁₋ₓ₎S₂x/ZnSe_{1-y}S_{y}, or (ZnSe)ₓ(CuInSe₂)₁₋ₓ/ZnSe_{1-y}S_{y} and x is from 0 to 1 and y is from 0 to 1 x is from greater than zero to less than 1, and y is from greater than zero to less than 1.

7. (canceled)

8. The quantum dot of claim 6, wherein the core is CdSe.

9. The quantum dot of claim 8, wherein the shell is Cd₁₋ₓZnₓS, and x is from greater than 0 to less than 1.

10. The quantum dot of claim 9, wherein xis 0.5.

11. (canceled)

12. The quantum dot of claim 1, comprising a CdSe core, a Cd_{0.5}Zn_{0.5}S shell having a shell thickness of from 3 nm to 10 nm, and a silica coating having a coating thickness of about 4 nm.

13. A composition, comprising one or more coated quantum dots of claim 1, and a polymer.

14. The composition of claim 13, wherein the polymer is a poly acrylate, a poly acryl methacrylate, a polyolefin, a polyvinyl, an epoxy resin (polyepoxide), a polycarbonate, a polyacetate, a polyamide, a polyurethane, a polyketone, a polyester, a polycyanoacrylate, a silicone, a polyglycol, a polyimide, a fluorinated polymer, a polycellulose, a poly oxazine, or a combination thereof.

15. The composition of claim 13, wherein:
the polymer is polyvinylpyrrolidones
an amount of the one or more quantum dots, excluding a weight of the silica coating, of from 10 mgs to 250 mgs per gram of polymer, or
a combination thereof.

16. (canceled)

17. The composition of claim 13, comprising one or more CdSe/Cd₁₋ₓZnₓS quantum dots, wherein x is from greater than zero to less than 1, and the polymer is polyvinylpyrrolidone.

18. The composition of claim 13, wherein the composition is a luminescent solar concentrator.

19. A device, comprising:
a substrate; and
a composition of claim 13.

20. The device of claim 19, wherein the composition is a thin film having a film thickness of from greater than zero to 1 mm.

21. The device of claim 20, wherein the thin film is a luminescent solar concentrator.

22. The device of claim 19, wherein the substrate is glass, fiberglass, acrylic sheet, or a combination thereof.

23. The device of claim 19, wherein the device further comprises one or more photovoltaic cells.

24. A method of making the silica coated type-I quantum dots of claim 1, the method comprising:
forming a composition comprising type-I quantum dots, a surfactant, and a solvent;
adding a silica precursor and an initiator to the composition; and
isolating the coated type-I quantum dots.

25. A method of making a device, the method comprising:
forming a composition comprising one or more of the coated quantum dots of claim 1, a polymer, and a solvent;
applying the composition to a substrate; and
evaporating the solvent.

26. The method of claim 25, comprising:
forming a composition comprising CdSe/Cd_{0.5}Zn_{0.5}S quantum dots having a silica coating, a polyvinylpyrrolidone polymer, and a solvent;
applying the composition to a glass substrate by a doctor-blade technique; and
evaporating the solvent to form a thin film luminescent solar concentrator comprising CdSe/Cd_{0.5}Zn_{0.5}S quantum dots having a silica coating and a polyvinylpyrrolidone polymer on the substrate.
